(19) United States
(12) Patent Application Publication
(10) Pub. No.: US 2026/0005132 A1
(43) Pub. Date: Jan. 1, 2026

(54) METAL INTERCONNECT STRUCTURES AND SEMI-DAMASCENE METHOD FOR FORMING THE SAME

(71) Applicant: Sandisk Technologies, Inc., Milpitas, CA (US)

(72) Inventors: Kensuke ISHIKAWA, Yokkaichi (JP); Fumitaka AMANO, Yokkaichi (JP)

(21) Appl. No.: 18/776,480

(22) Filed: Jul. 18, 2024

Related U.S. Application Data
(60) Provisional application No. 63/664,850, filed on Jun. 27, 2024.

(51) Int. Cl. H01L 23/522; H01L 21/768; H01L 23/528; H01L 23/532; H10B 41/10; H10B 41/27; H10B 41/30; H10B 41/40; H10B 43/10; H10B 43/27; H10B 43/30; H10B 43/40

(52) U.S. Cl. CPC H01L 23/5226; H01L 21/76807; H01L 21/76816; H01L 21/7682; H01L 21/76843; H01L 21/76877; H01L 23/528; H01L 23/53238; H10B 41/10; H10B 41/27; H10B 41/30; H10B 41/40; H10B 43/10; H10B 43/27; H10B 43/30; H10B 43/40

(57) ABSTRACT

A first integrated line-and-via structure includes a first via portion embedded within at least one via-level dielectric layer and a first line portion embedded within a lower portion of a dielectric matrix that contacts a top surface of the at least one via-level dielectric layer within a first horizontal plane. The first integrated line-and-via structure includes a first metallic barrier liner and a first main metal portion including a planar portion having sidewalls in direct contact with first surface segments of the dielectric matrix. A second integrated line-and-via structure includes a second via portion contacting the first line portion and further includes a second line portion adjoined to a top end of the second via portion.

### FIELD

The present disclosure relates generally to the field of semiconductor devices, and particularly to metal interconnect structures and a semi-damascene method for forming the same.

### BACKGROUND

Continued scaling of semiconductor devices lead to higher density metal wiring structures. As the lateral dimensions of the metal lines and metal vias shrink, traditional dual damascene line and via interconnect structure formation may no longer be sufficient to provide the sufficiently high metal wiring density.

### SUMMARY

According to an aspect of the present disclosure, a device structure comprises: a first integrated line-and-via structure comprising a first via portion embedded within at least one via-level dielectric layer and a first line portion embedded within a lower portion of a dielectric matrix that contacts a top surface of the at least one via-level dielectric layer within a first horizontal plane, wherein the first integrated line-and-via structure comprises a first metallic barrier liner containing a vertically-extending portion that contacts a sidewall of the at least one via-level dielectric layer and a horizontally-extending portion that contacts a segment of a top surface of the at least one via-level dielectric layer, and further comprises a first main metal portion including a planar portion that overlies the horizontally-extending portion of the first metallic barrier liner and has sidewalls in direct contact with first surface segments of the dielectric matrix; and a second integrated line-and-via structure comprising a second via portion contacting a first segment of a top surface of the first line portion of the first integrated line-and-via structure within a second horizontal plane and further comprising a second line portion adjoined to a top end of the second via portion.

According to another aspect of the present disclosure, a three-dimensional memory device comprises an alternating stack of insulating layers and word lines; memory opening fill structures extending through the alternating stack and each comprising a memory film, a vertical semiconductor channel, and a drain region; copper bit lines electrically connected to the drain regions; copper bit-line-level interconnect metal lines located at a same level as the copper bit lines and electrically connected to the word lines; first integrated line-and-via structures contacting the respective copper bit lines and copper bit-line-level interconnect metal lines, and comprising a tungsten nitride metallic barrier liner and a tungsten first main metal portion; and second integrated line-and-via structures contacting the respective first integrated line-and-via structures and comprising a second metallic barrier liner and a copper second main metal portion.

According to another aspect of the present disclosure, a method of forming device structure comprises: forming a first via cavity through at least one via-level dielectric layer; depositing and patterning a first metallic barrier material, a first main metal, and a dielectric hardmask material over the at least one via-level dielectric layer, wherein a patterned portion of the first metallic barrier material and the first main metal comprises a first integrated line-and-via structure that includes a first via portion embedded within the at least one via-level dielectric layer and a first line portion overlying a first horizontal plane including a top surface of the at least one via-level dielectric layer, and a patterned portion of the dielectric hardmask material comprises a dielectric hardmask rail that overlies the first line portion; forming a dielectric matrix over the dielectric hardmask rail and the at least one via-level dielectric layer; forming a line cavity in an upper portion of the dielectric matrix such that a first portion of the dielectric hardmask rail is exposed while a second portion of the dielectric hardmask rail is not exposed; forming a second via cavity by removing the first portion of the dielectric hardmask rail without removing the second portion of the dielectric hardmask rail; and forming a second integrated line-and-via structure in a combined volume of the line cavity and the second via cavity.

### BRIEF DESCRIPTION OF THE DRAWINGS

FIG. 1A is a schematic vertical cross-sectional view of an exemplary structure after formation of memory opening fill structures and support pillar structures according to an embodiment of the present disclosure.

FIG. 1B is a top-down view of the exemplary structure of FIG. 1A. The vertical plane A-A is the cut plane of the vertical cross-sectional view of FIG. 1A.

FIG. 1C is a vertical cross-sectional view of a region of the exemplary structure around a memory opening fill structure.

FIG. 2A is a vertical cross-sectional view of the exemplary structure after formation of lateral isolation trenches according to an embodiment of the present disclosure.

FIG. 2B is a top-down view of the exemplary structure of FIG. 2A. The vertical plane A-A is the cut plane of the vertical cross-sectional view of FIG. 2A.

FIG. 3 is a schematic vertical cross-sectional view of the exemplary structure after formation of electrically conductive layers according to an embodiment of the present disclosure.

FIG. 4A is a vertical cross-sectional view of the exemplary structure after formation of lateral isolation trench fill structures, layer contact via structures, and drain contact via structures according to an embodiment of the present disclosure.

FIG. 4B is a top-down view of the exemplary structure of FIG. 4A. The vertical plane A-A is the cut plane of the vertical cross-sectional view of FIG. 4A.

FIG. 5A is a vertical cross-sectional view of the exemplary structure after formation of bit-line-level metal interconnect structures according to an embodiment of the present disclosure.

FIG. 5B is a top-down view of the exemplary structure of FIG. 5A. The vertical plane A-A is the cut plane of the vertical cross-sectional view of FIG. 5A.

FIGS. 6A-6K are sequential vertical cross-sectional views of a region of the exemplary structure during formation of first integrated line-and-via structures and second integrated line-and-via structures according to an embodiment of the present disclosure.

FIG. 7 is a vertical cross-sectional view of the exemplary structure after formation of a memory die according to an embodiment of the present disclosure.

FIG. 8 is a vertical cross-sectional view of a logic die according to an embodiment of the present disclosure.

FIG. 9 is a vertical cross-sectional view of the exemplary structure after attaching the logic die to the memory die according to an embodiment of the present disclosure.

FIG. 10 is a vertical cross-sectional view of the exemplary structure after removal of the substrate according to an embodiment of the present disclosure.

FIG. 11A is a vertical cross-sectional view of the exemplary structure after formation of source structures according to an embodiment of the present disclosure.

FIG. 11B is a magnified view of a region of the exemplary structure of FIG. 11A.

FIG. 12 is a vertical cross-sectional view of the exemplary structure after formation of a backside dielectric layer and source contact structures according to an embodiment of the present disclosure.

### DETAILED DESCRIPTION

As discussed above, the embodiments of the present disclosure are directed to metal interconnect structures and semi-damascene methods for forming the same, the various aspects of which are described below. Embodiments of the disclosure can be employed to form various structures including high-density metal interconnect structures for semiconductor devices, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

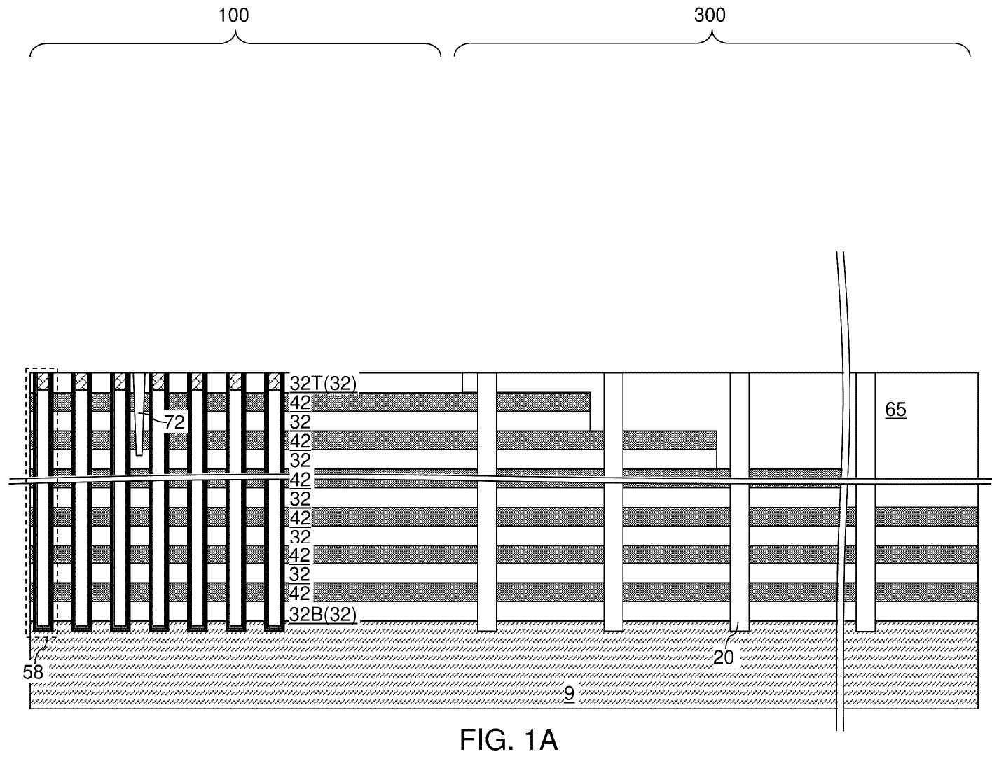

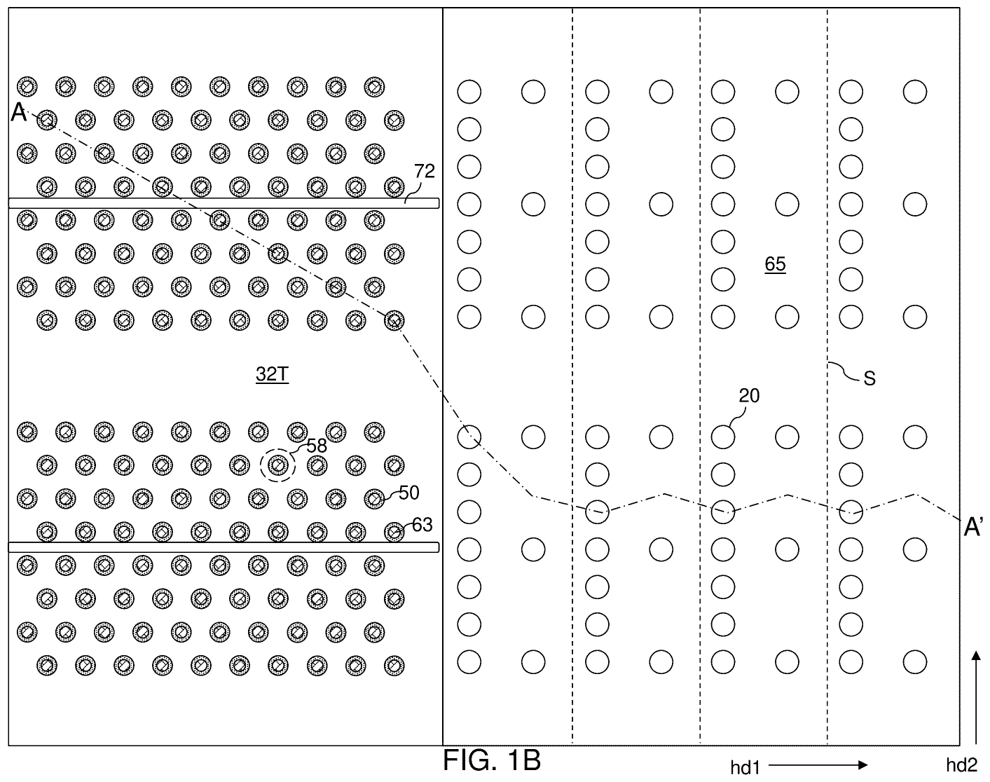

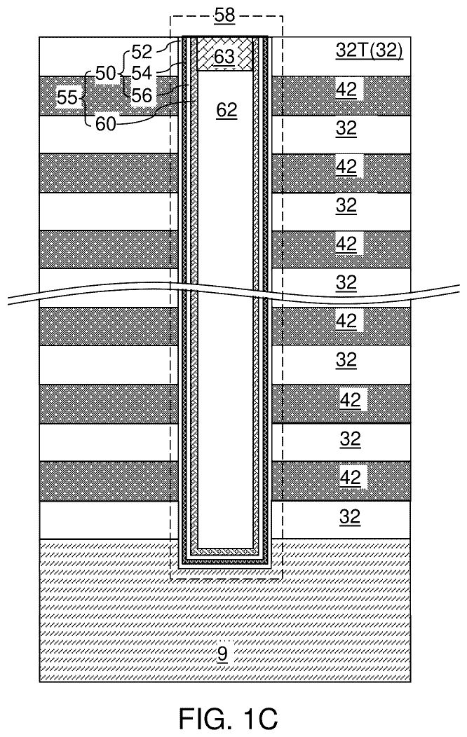

Referring to FIGS. 1A-1C, an exemplary structure according to an embodiment of the present disclosure is illustrated. The exemplary structure comprises a substrate 9, which may be a semiconductor substrate or a conductive substrate. For example, the substrate 9 may comprise a commercially available silicon wafer. Alternatively, the substrate 9 may comprise any material that may be removed selective the materials of insulating layers 32 and dielectric material portions to be subsequently formed.

An alternating stack of first material layers and second material layers can be formed over the substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 can be formed through a subset of the material layers in the alternating stack (32, 42) that is located in the top portion of the alternating stack (32, 42). The drain-select-level isolation structures 72 may laterally extend along the first horizontal direction hd1.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

Stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

A first etch mask layer (not shown) can be formed over the alternating stack (32, 42), and can be lithographically patterned to form openings in the contact region 300. An anisotropic etch process can be performed to transfer the pattern of the openings in the first etch mask layer through the stepped dielectric material portion 65 and the alternating stack (32, 42). Support openings can optionally be formed through the stepped dielectric material portion 65 and the alternating stack (32, 42) in the contact region 300. Each of the support openings can vertically extend into the substrate 9. In one embodiment, bottom surfaces of the support openings may be formed at or below the top surface of the substrate 9. The support openings may have a diameter in a range from 60 nm to 400 nm, such as from 120 nm to 300 nm, although lesser and greater thicknesses may be employed.

A dielectric fill material, such as silicon oxide, can be deposited in the support openings by a conformal deposition process. Excess portions of the dielectric fill material can be removed from above the top surface of the topmost insulating layer 32T, for example, by a recess etch process. Each portion of the dielectric fill material that fills a respective support opening constitutes a support pillar structure 20, which can be employed to provide structural support to the insulating layers 32 and the stepped dielectric material portion 65 during replacement of the sacrificial material layers 42 with electrically conductive layers. Alternatively, the support openings can be formed at a later step at the same time as the memory openings, and the support pillar structures 20 can be formed in the support openings at the same time as the memory opening fill structures are formed in the memory openings, as will be described below.

A second etch mask layer can be formed over the alternating stack (32, 42), and can be lithographically patterned to form openings in the memory array region 100. An anisotropic etch process can be performed to transfer the pattern of the openings in the second etch mask layer through the alternating stack (32, 42). Memory openings can be formed through the alternating stack (32, 42) in the memory array region 100.

Each cluster of memory openings may comprise a plurality of rows of memory openings. Each row of memory openings may comprise a plurality of memory openings that are arranged along the first horizontal direction hd1 with a uniform pitch. The rows of memory openings may be laterally spaced among one another along the second horizontal direction hd2, which may be perpendicular to the first horizontal direction hd1. In one embodiment, each cluster of memory openings may be formed as a two-dimensional periodic array of memory openings. The memory openings may have a diameter in a range from 60 nm to 400 nm, such as from 120 nm to 300 nm, although lesser and greater thicknesses may be employed. In the alternative embodiment, the support openings are formed at the same time as the memory openings using the same patterned photoresist layer.

A memory opening fill structure 58 can be formed in each memory opening. For example, a layer stack including a memory material layer 54 can be conformally deposited in each memory opening. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

A semiconductor channel material layer can be deposited over each memory film 50 by performing a conformal deposition process. If the semiconductor channel material layer is doped, the semiconductor channel material layer may have a doping of a first conductivity type, which may be p-type or n-type. The thickness of the semiconductor channel material layer may be in a range from 5 nm to 50 nm, such as from 10 nm to 30 nm, although lesser and greater thicknesses may also be employed.

A dielectric core layer comprising a dielectric fill material, such as silicon oxide, can be deposited in remaining volumes of the memory openings. While the dielectric core layer can be deposited employing a conformal deposition process, such as a chemical vapor deposition process, the conformity of the conformal deposition process may not be perfect. Thus, the thickness of a bottom portion of the dielectric core layer at the bottom of each memory opening may be less than the thickness of an upper portion of the dielectric core layer at the top of each memory opening. The dielectric core layer can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

A doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer (which has a doping of the first conductivity type) constitutes a vertical semiconductor channel 60.

Each portion of the layer stack including the memory material layer 54 that remains in a respective memory opening constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers. In the alternative embodiment, the support pillar structures 20 may be formed in the support openings at the same time as the memory opening fill structures 58 are formed in the memory openings. In this case, the support pillar structures 20 comprise the same materials as the memory opening fill structures 58.

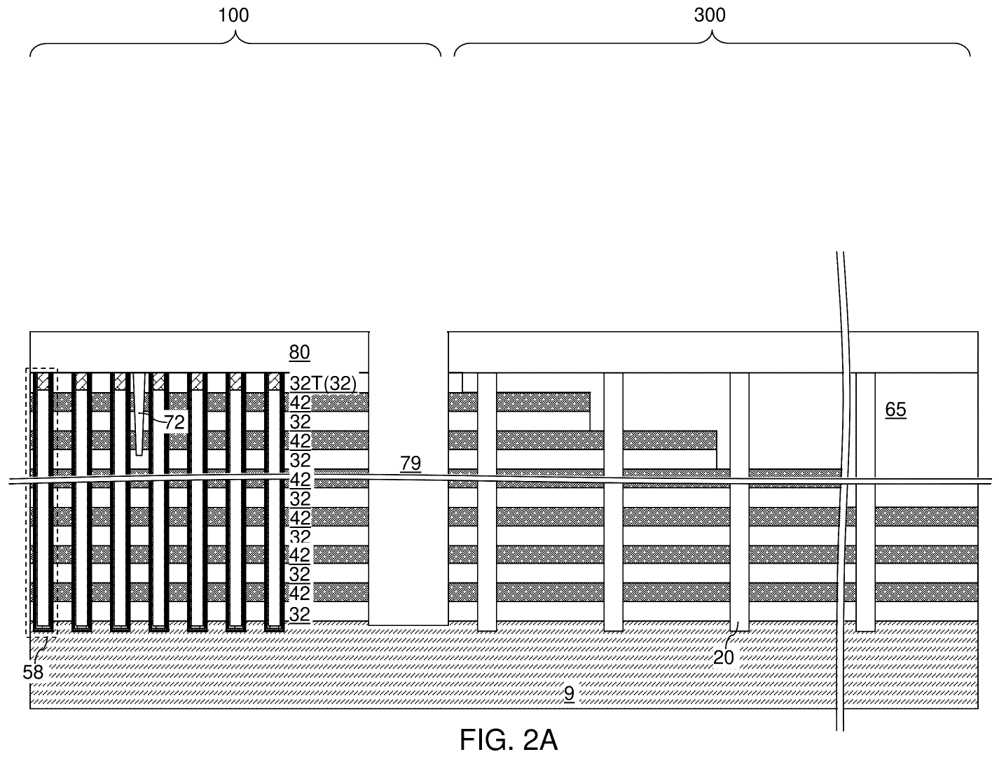

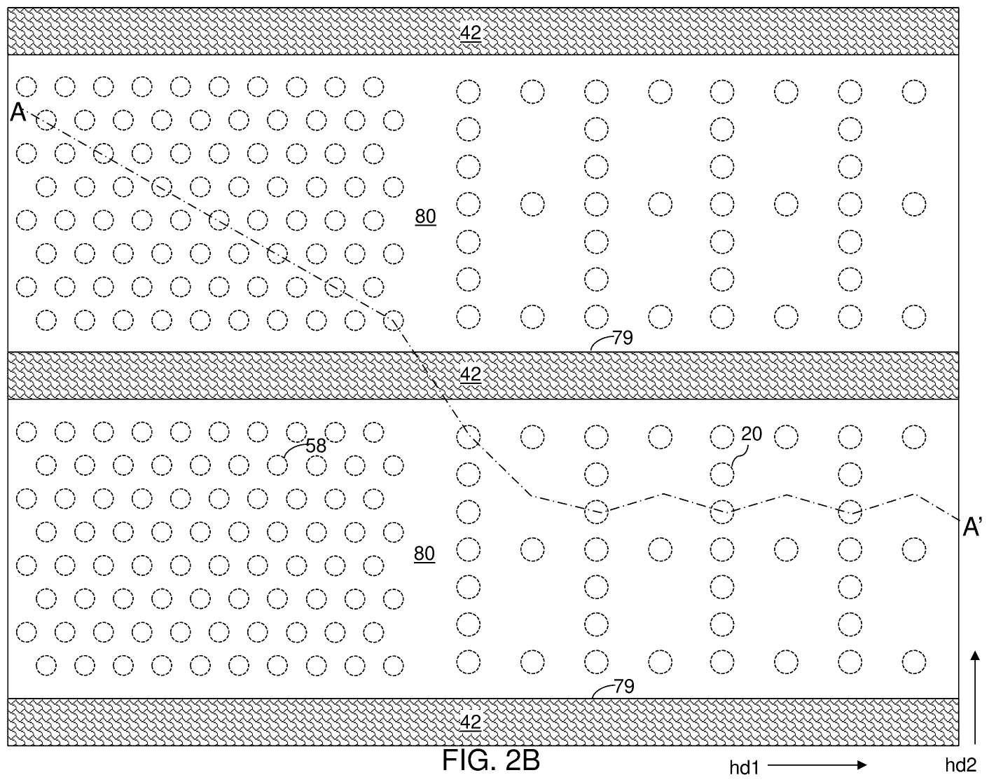

Referring to FIGS. 2A and 2B, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the substrate 9. The photoresist layer can be subsequently removed, for example, by ashing.

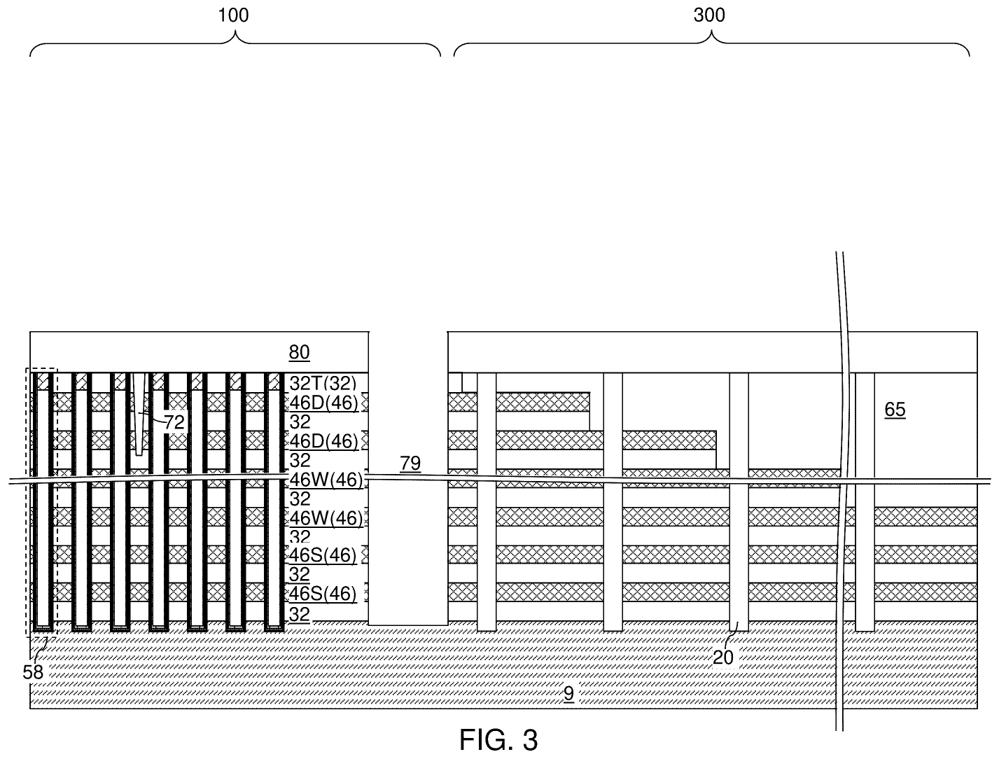

Referring to FIG. 3, an etchant that selectively etches the material of the sacrificial material layers 42 with respect to the material of the insulating layers 32 can be introduced into the access trenches 79, for example, employing an isotropic etch process. Lateral recesses are formed in volumes from which the sacrificial material layers 42 are removed. The removal of the sacrificial material layers 42 can be selective to the materials of the insulating layers 32, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the access trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses are present within volumes previously occupied by the sacrificial material layers 42.

Each lateral recess can be a laterally extending cavity having a lateral dimension that is greater than the vertical extent of the cavity. In other words, the lateral dimension of each lateral recess can be greater than the height of the lateral recess. A plurality of lateral recesses can be formed in the volumes from which the second material of the sacrificial material layers 42 is removed. The memory openings in which the memory stack structures 55 are formed are herein referred to as front side openings or front side cavities in contrast with the lateral recesses.

Each of the plurality of lateral recesses can extend substantially parallel to the top surface of the substrate 9. A lateral recess can be vertically bounded by a top surface of an underlying insulating layer 32 and a bottom surface of an overlying insulating layer 32. In one embodiment, each lateral recess can have a uniform height throughout.

An outer blocking dielectric layer can be optionally formed. The outer blocking dielectric layer, if present, comprises a dielectric material that functions as a control gate dielectric for the control gates to be subsequently formed in the lateral recesses. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses by providing at least one reactant gas into the lateral recesses through the access trenches 79. A metallic barrier layer can be deposited in the lateral recesses. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses, on the sidewalls of the at least one the access trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses, and a continuous metallic material layer can be formed on the sidewalls of each access trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the access trenches 79 or above the contact-level dielectric layer 80.

The deposited metallic material of the continuous electrically conductive material layer is etched back from the sidewalls of each access trench 79 and from above the contact-level dielectric layer 80 by performing an isotropic etch process that etches the at least one conductive material of the continuous electrically conductive material layer. Each remaining portion of the deposited metallic material in the lateral recesses constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses.

At least one uppermost electrically conductive layer 46 may comprise at least one drain side select gate electrode 46D. At least one bottommost electrically conductive layer 46 may comprise at least one source side select gate electrode 46S. The remaining electrically conductive layers 46 may comprise word lines 46W. Each word line functions as a common control gate electrode for the plurality of vertical NAND strings (e.g., memory opening fill structures 58).

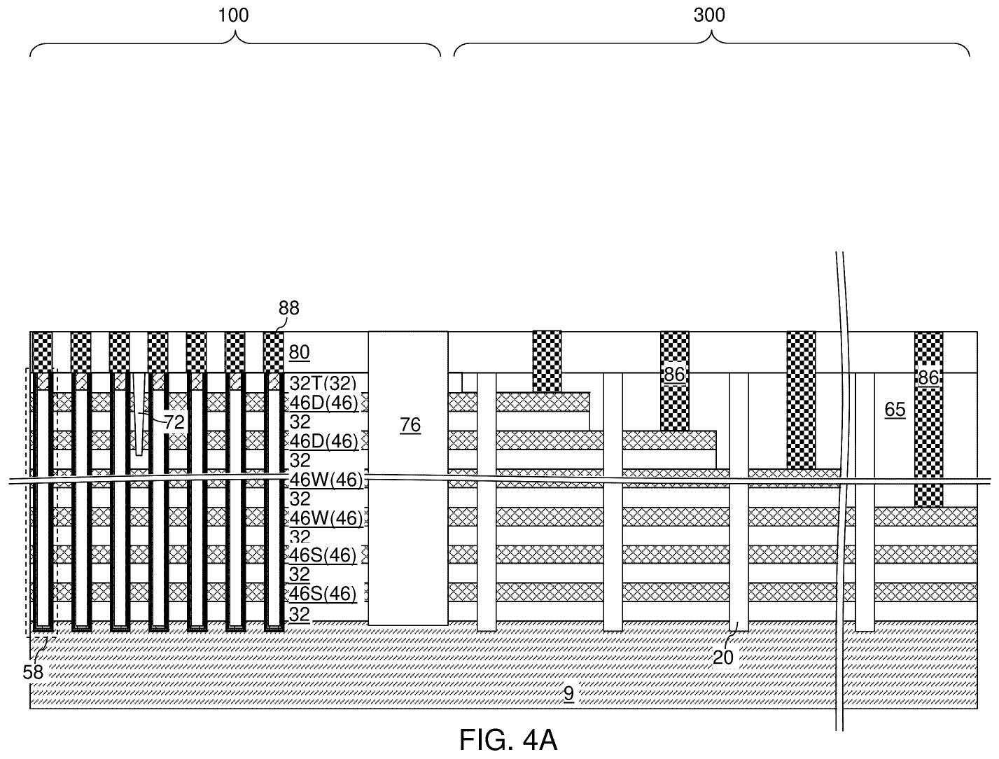

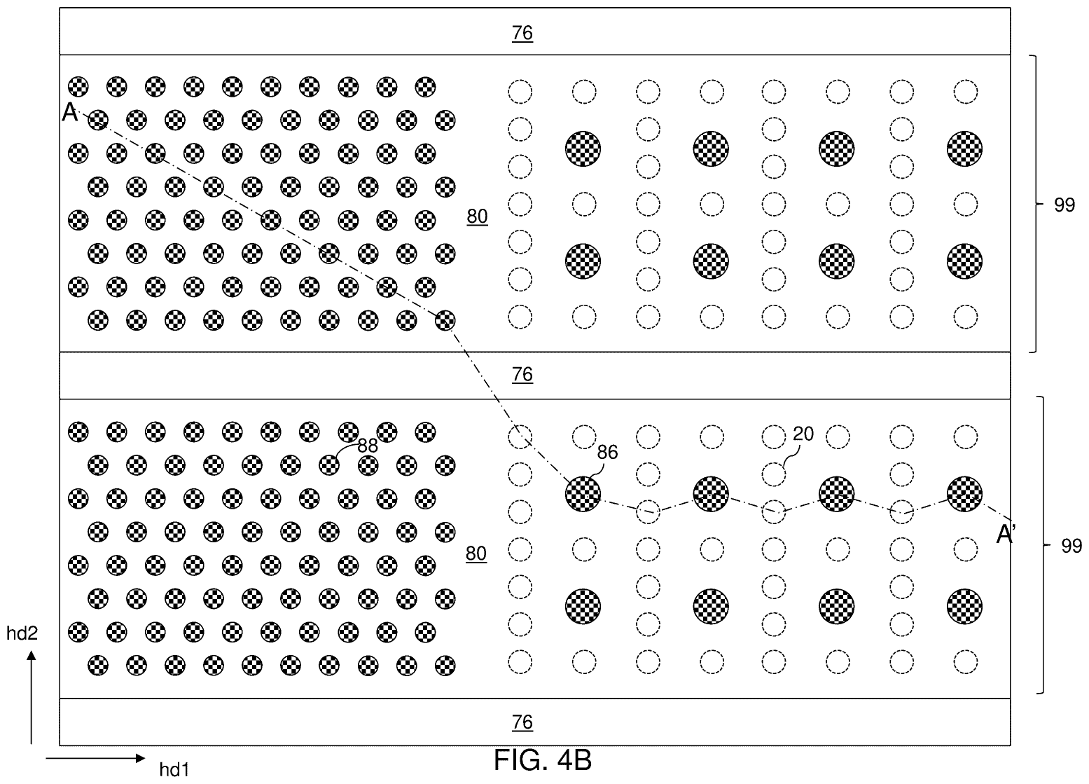

Referring to FIGS. 4A and 4B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure. The areas between adjacent lateral isolation trench fill structures 76 correspond to respective memory blocks (99A, 99B), as shown in FIG. 4B.

Contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

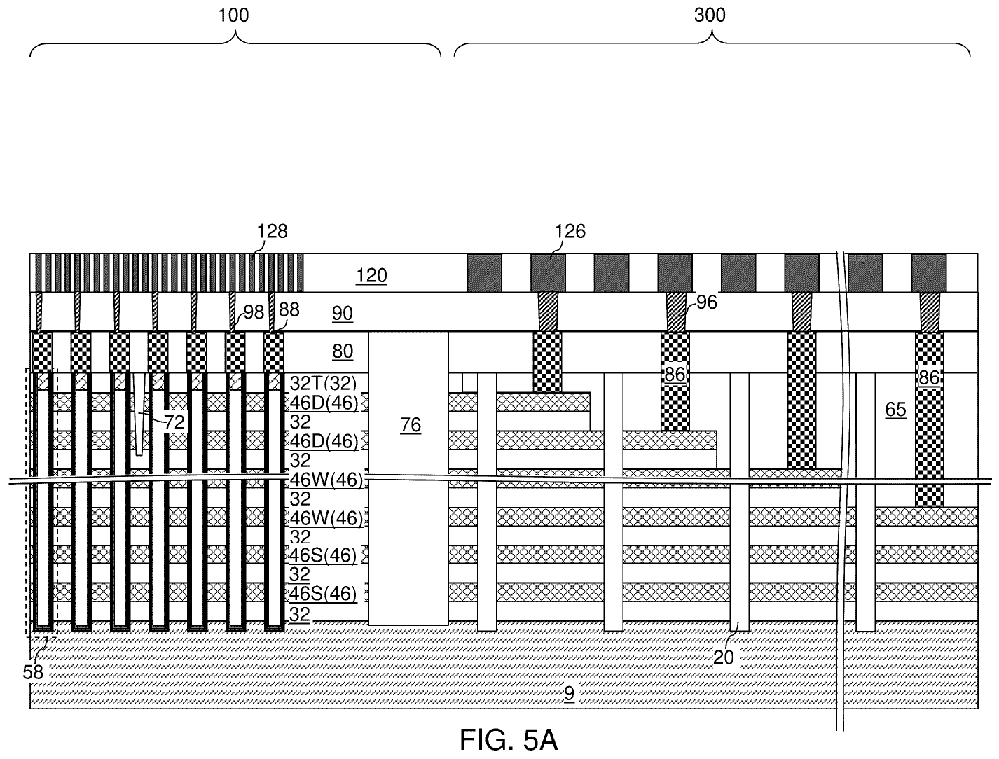

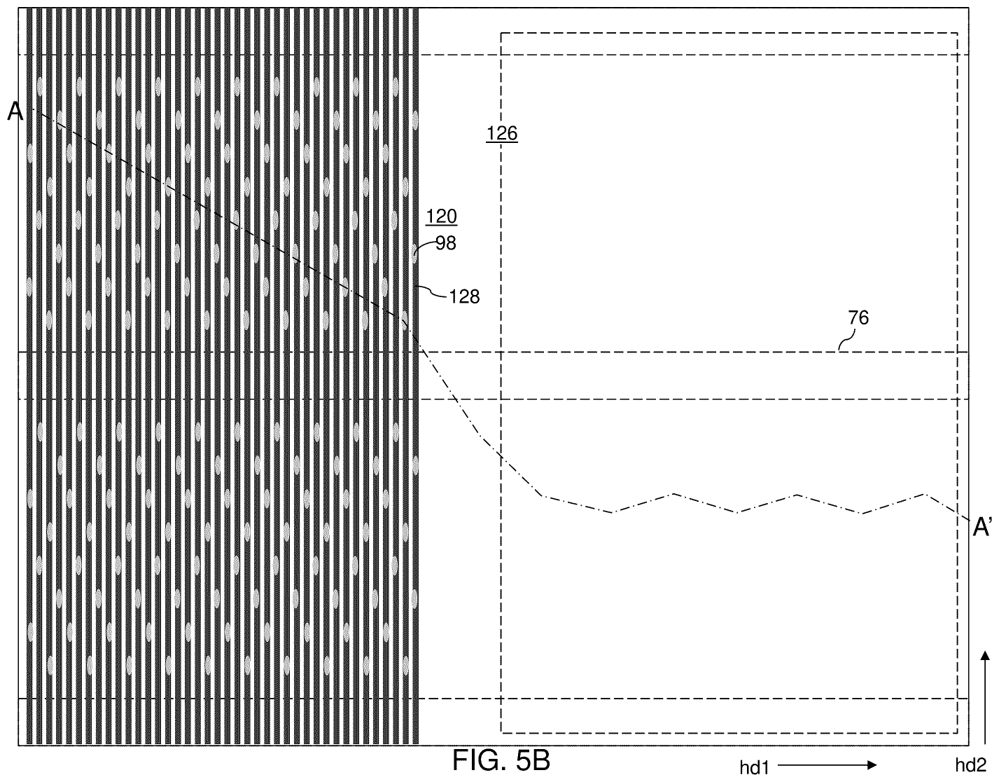

Referring to FIGS. 5A and 5B, a bit-line-level dielectric layer 120 can be formed above the contact-level dielectric layer 80. Bit-line-level line cavities can be formed through the bit-line-level dielectric layer 120, and can be filled with at least one conductive material (which may comprise at least one metallic material) to form bit-line-level metal lines (128, 126). The bit-line-level metal lines (128, 126) may comprise bit lines 128 that laterally extend along the second horizontal direction hd2, and bit-line-level interconnect metal lines 126 (shown in FIG. 5A and schematically shown in FIG. 5B) that can be employed to provide electrical connection to the layer contact via structures 86. The bit-line-level interconnect metal lines 126 provide an electrical connection between the word lines 46 and the word line driver circuit to be provided in a logic die, which is described in more detail below.

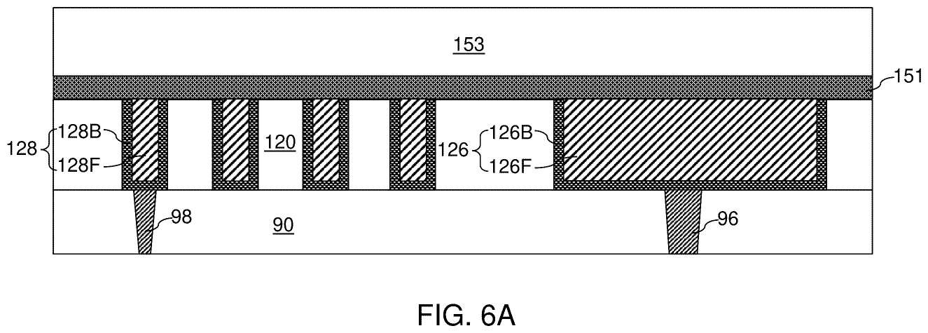

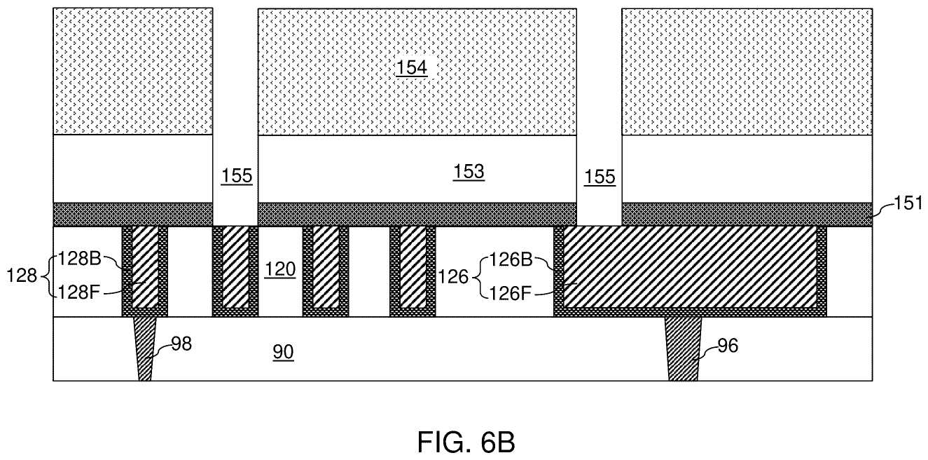

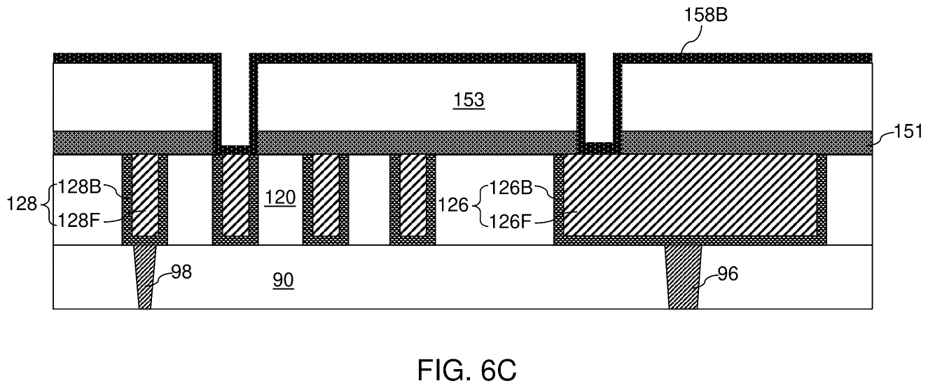

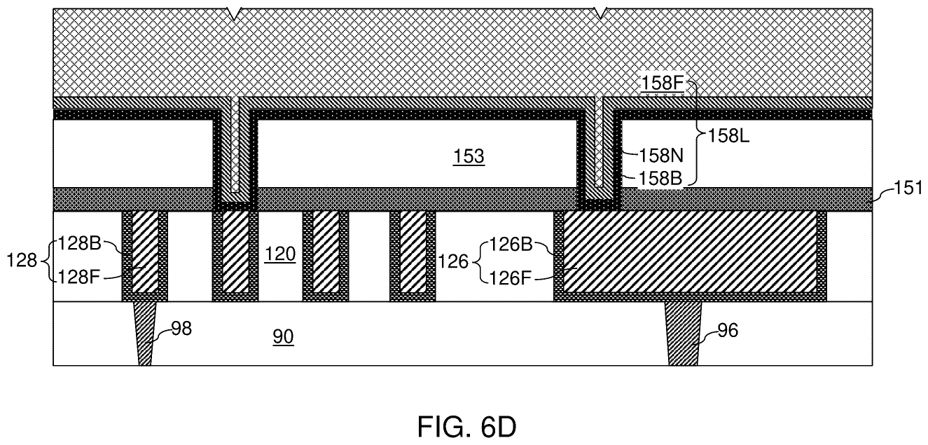

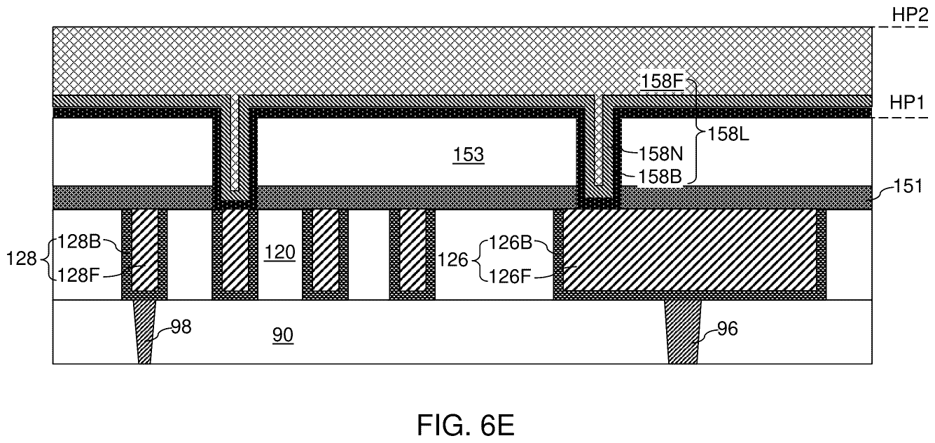

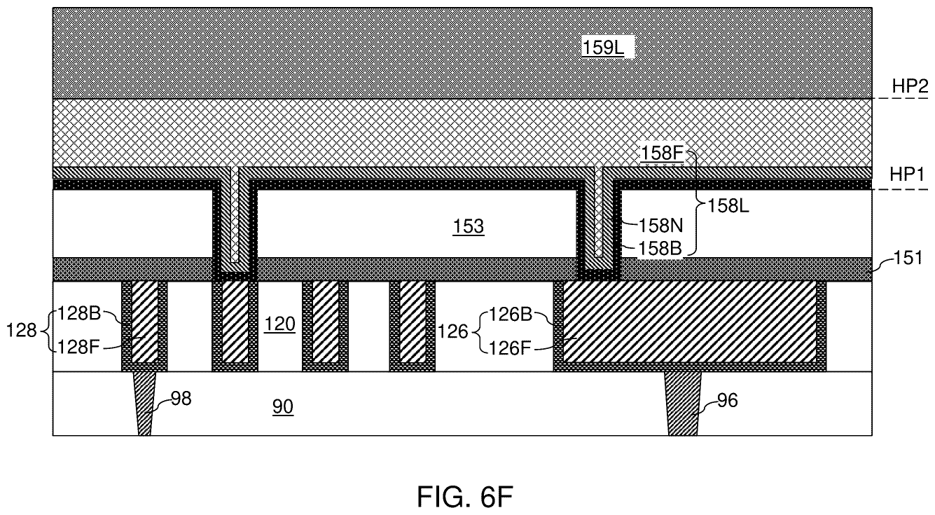

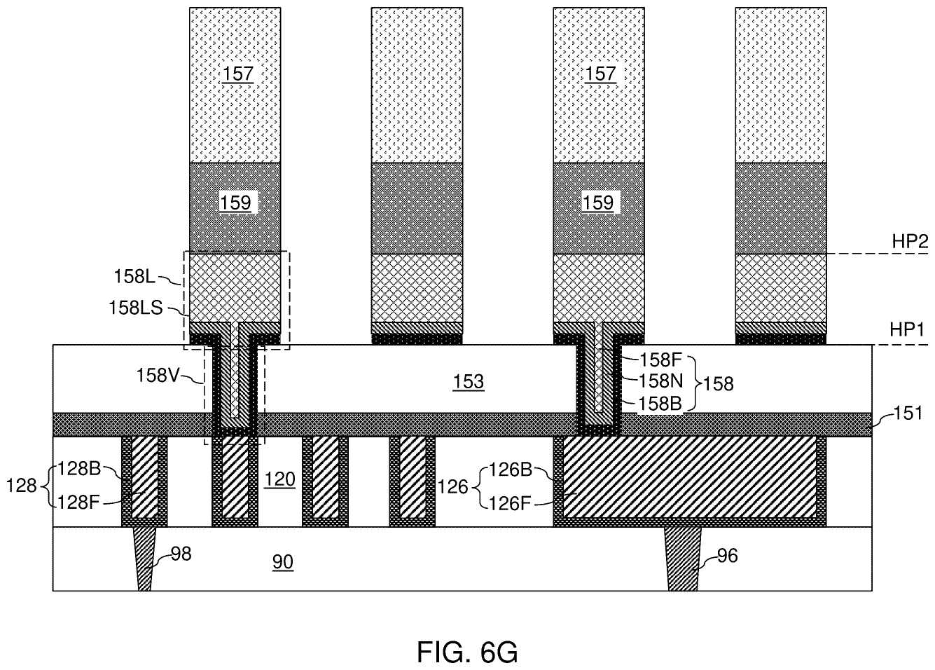

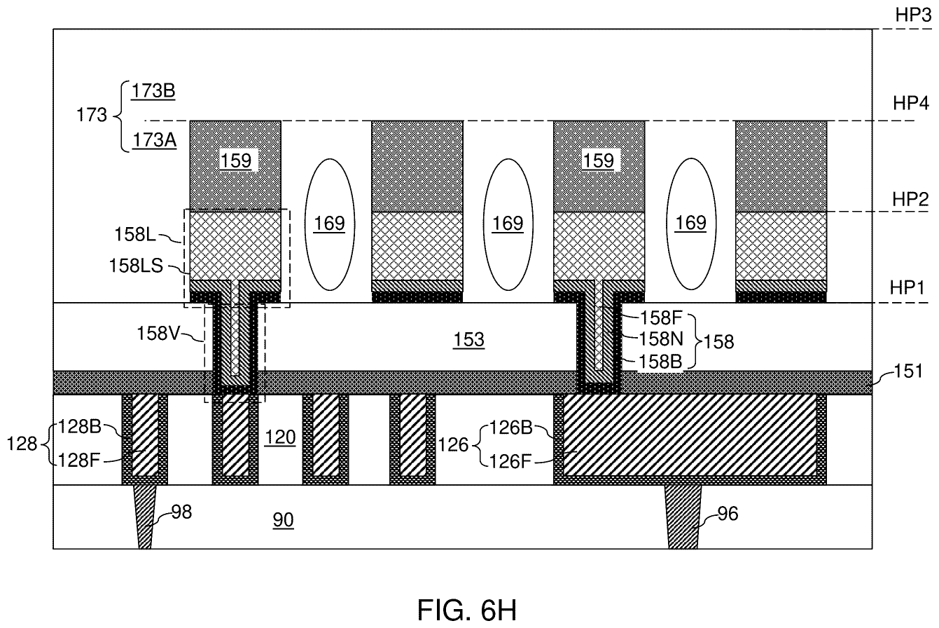

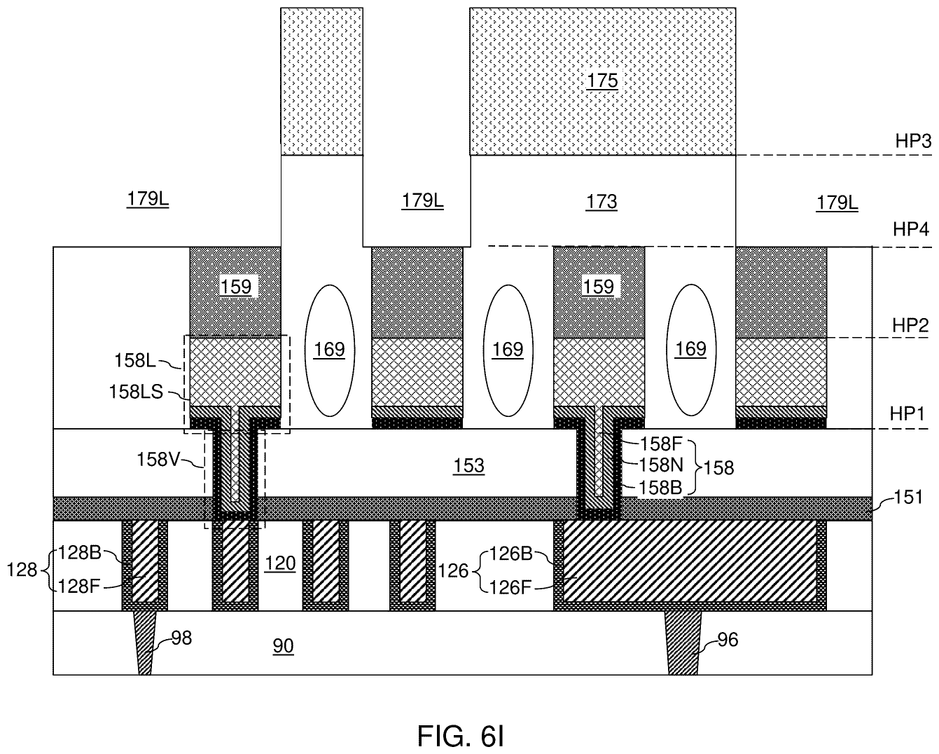

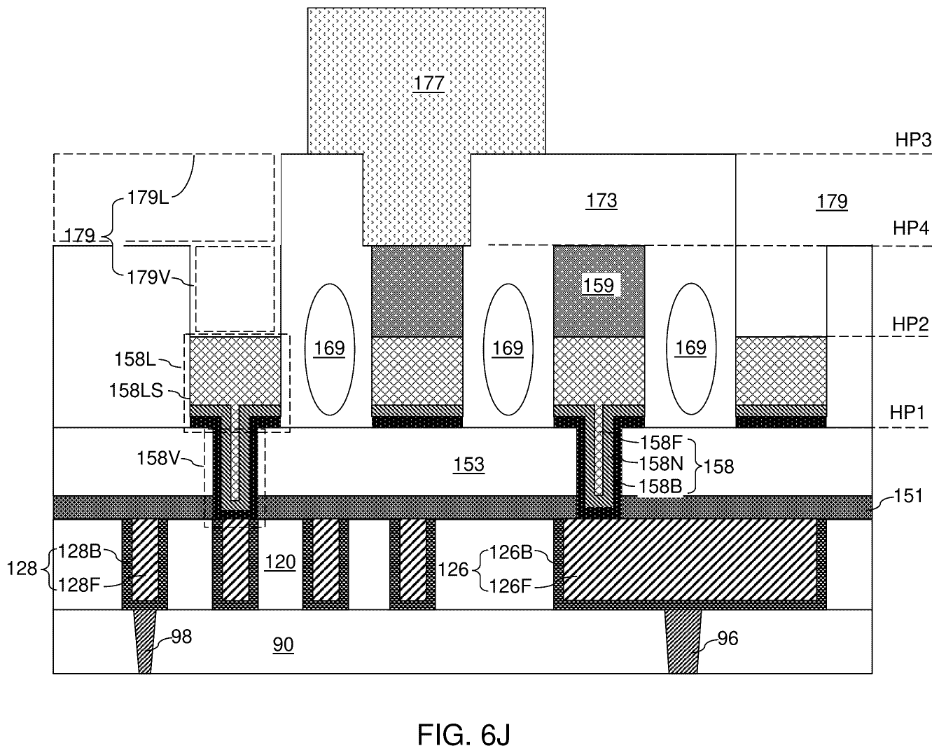

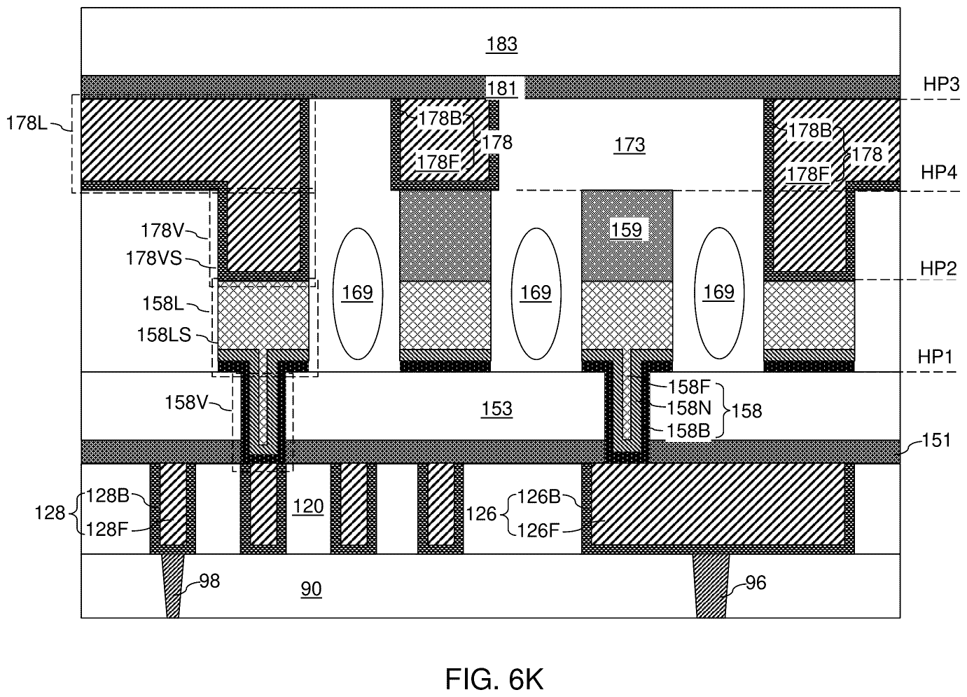

FIGS. 6A-6K are sequential vertical cross-sectional views of a region of the exemplary structure during formation of first integrated line-and-via structures 158 and second integrated line-and-via structures 178 according to an embodiment of the present disclosure.

Referring to FIG. 6A, a region of the exemplary structure is shown around a set of bit lines 128 and a bit-line-level interconnect metal line 126. Each bit line 128 may comprises a combination of a bit-line metallic liner 128B and a bit-line main metal portion 128F. Each bit-line-level interconnect metal line 126 may comprise a combination of a bit-line-level metallic liner 126B and a bit-line-level main metal portion 126F. Each bit-line metallic liner 128B and each bit-line-level metallic liner 126B comprises a metallic diffusion barrier material such as TiN, TaN, WN, MON, Ti, Ta and/or a stack thereof. Each bit-line main metal portion 128F and each bit-line-level main metal portion 126F comprises, and/or consists essentially of, a metal, which may be selected from W, Cu, Co, Mo, Ru, etc. In one embodiment, the bit-line-level main metal portion 126F comprises copper.

At least one via-level dielectric layer (151, 153) can be formed over the bit-line-level dielectric layer 120. The at least one via-level dielectric layer (151, 153) may comprise, for example, an optional via-level etch-stop dielectric layer 151 and a via-level main dielectric layer 153. The via-level etch-stop dielectric layer 151 comprises an etch-stop dielectric material, i.e., a dielectric material that is different from the material of the via-level main dielectric layer 153 and can effectively function as an etch-stop material during a subsequent etch step that etches the material of the via-level main dielectric layer 153. In one embodiment, the via-level etch-stop dielectric layer 151 may comprise silicon carbonitride (SiCN), silicon nitride, silicon oxynitride, or a dielectric metal oxide (such as aluminum oxide or a transition metal oxide). In one embodiment, the via-level etch-stop dielectric layer 151 comprises silicon carbonitride. The thickness of the via-level etch-stop dielectric layer 151 may be in a range from 5 nm to 30 nm, such as from 10 nm to 20 nm, although lesser and greater thicknesses may also be employed.

The via-level main dielectric layer 153 comprises an interlayer dielectric (ILD) material such as undoped silicate glass (i.e., silicon oxide), a doped silicate glass, or a porous or non-porous organosilicate glass. The via-level main dielectric layer 153 may have a thickness in a range from 50 nm to 300 nm, although lesser and greater thicknesses may also be employed.

Referring to FIG. 6B, a photoresist layer 154 can be applied over the at least one via-level dielectric layer (151, 153), and can be lithographically patterned to form discrete openings that each overlie a respective one of the bit lines 128 or a respective one of the bit-line-level interconnect metal lines 126. An anisotropic etch process can be performed to transfer the pattern of the discrete openings in the photoresist layer 154 through the at least one via-level dielectric layer (151, 153). In one embodiment, the anisotropic etch process may comprise a first anisotropic etch step that etches unmasked portions of the via-level main dielectric layer 153 selective to the material of the via-level etch-stop dielectric layer 151, and a second anisotropic etch step that etches unmasked portions of the via-level etch-stop dielectric layer 151 selective to the materials of the bit lines 128 and the bit-line-level interconnect metal lines 126. First via cavities 155 are formed in volumes from which the materials of the at least one via-level dielectric layer (151, 153) are etched. The sidewalls of the first via cavities 155 may vertically extend from the topmost surface of the at least one via-level dielectric layer (151, 153) to the bottommost surface of the at least one via-level dielectric layer (151, 153). The photoresist layer 154 can be subsequently removed, for example, by ashing.

Referring to FIG. 6C, a first metallic barrier liner 158B can be deposited in peripheral regions of the first via cavities 155 and above the topmost surface of the at least one via-level dielectric layer (151, 153). The first metallic barrier liner 158B comprises, and/or consist essentially of, a conductive metallic barrier material, such as a metallic nitride material. For example, the first metallic barrier liner 158B may comprise, and/or may consist essentially of, TiN, TaN, WN, and/or MoN. In one embodiment, the first metallic barrier liner 158B comprises WN. Tungsten nitride (i.e., WN) can be deposited at a lower temperature than TiN and can reduce sheet resistance of an overlying tungsten layer more than TiN. The first metallic barrier liner 158B may be formed by physical vapor deposition and/or chemical vapor deposition. The thickness of vertically-extending portions of the first metallic barrier liner 158B on the sidewalls of the first via cavities 155 may be in a range from 2 nm to 20 nm, such as from 3 nm to 10 nm, although lesser and greater thicknesses may also be employed.

Referring to FIG. 6D, a first main metal layer (158N, 158F) comprising and/or consisting essentially of a first metal can be subsequently deposited in remaining volumes of the first via cavities 155 and above the horizontally-extending portion of the first metallic barrier liner 158B that overlies the topmost surface of the at least one via-level dielectric layer (151, 153). In one embodiment, the first main metal layer (158N, 158F) consists essentially of a refractory metal, such as tungsten, tantalum or molybdenum. In one embodiment, first main metal layer (158N, 158F) comprises or consists essentially of tungsten. The combination of the first metallic barrier liner 158B and the first main metal layer (158N, 158F) constitutes a first metal layer 158L.

In some embodiments, the first main metal layer (158N, 158F) comprises tungsten deposited employing a two-step deposition process. In this case, a tungsten nucleation layer 158N is first deposited on the first metallic barrier liner 158B employing a nucleation process, and a bulk tungsten layer 158F is subsequently deposited on the tungsten nucleation layer 158N employing a bulk metal deposition process. For example, the nucleation process may comprise a first chemical vapor deposition process in which a nucleation agent gas (such as silane or diborane, etc.) is flowed into a process chamber in conjunction with a tungsten-containing precursor gas, such as tungsten hexafluoride, and the bulk metal deposition process may comprise a second chemical vapor deposition process in which the tungsten-containing precursor gas, such as tungsten hexafluoride, is flowed into the process chamber without use of the nucleation agent gas.

Referring to FIG. 6E, in case the top surface of the first main metal layer (158N, 158F) includes any divot over the areas of the first via cavities 155, a planarization process, such as a chemical mechanical polishing process, may be optionally performed. The top surface of the first main metal layer (158N, 158F) may be a planar surface after the planarization process. If divots are not present on the topmost surface of the first main metal layer (158N, 158F), the planarization process may be omitted. Generally, the bottom surface of a horizontally-extending portion of the first metal layer 158L (i.e., the portion outside the first via cavities 155) may be formed within a first horizontal plane HP1 that includes the topmost surface of the at least one via-level dielectric layer (151, 153), and the top surface of the first metal layer 158L may be formed within a second horizontal plane HP2. The thickness of a horizontally-extending portion of the first metal layer 158L, which is defined as the vertical distance between the first horizontal plane HP1 and the second horizontal plane HP2, may be in a range from 50 nm to 200 nm, although lesser and greater thicknesses may also be employed.

Referring to FIG. 6F, a dielectric hardmask material can be deposited over the first metal layer 158L to form a dielectric hardmask material layer 159L. The dielectric hardmask material layer 159L comprises a dielectric material that can be subsequently employed as a hardmask material for etching the materials of the first metal layer 158L and as an etch stop material during a subsequent line cavity etching step. The dielectric material of the dielectric hardmask layer 159L comprise a material that may be removed selective to an interlayer dielectric (ILD) material of a dielectric matrix to be subsequently formed. For example, the dielectric hardmask layer 159L may comprise silicon nitride. The dielectric hardmask layer 159L may be deposited, for example, by plasma-enhanced chemical vapor deposition. The thickness of the dielectric hardmask layer 159L may be in a range from 30 nm to 150 nm, such as from 50 nm to 100 nm, although lesser and greater thicknesses may also be employed.

Referring to FIG. 6G, a patterned etch mask layer, such as a first patterned photoresist layer 157, can be formed over the dielectric hardmask layer 159L by depositing a blanket photoresist layer and lithographically patterning the blanket photoresist layer through exposure and development. The pattern of the remaining portions of the photoresist material in the first patterned photoresist layer 157 may comprise a line-and-space pattern. A line-and-space pattern refers to periodic repetition of a unit pattern including a line pattern having a uniform line width and a space pattern having a uniform space width. The total width of the unit pattern is referred to as a pitch of the line-and-space pattern. As such, the line-and-space pattern has a one-dimensional periodicity along the widthwise direction of the line patterns. The lengthwise direction of the line-and-space pattern may be any horizontal direction. In one embodiment, the lengthwise direction of the line-and-space pattern may be parallel to the lengthwise direction (i.e., bit line direction) of the bit lines 128. It is understood that the drawings are schematic, and the lateral extension direction (i.e., the lengthwise direction) of the line-and-space pattern may be any horizontal direction that may be parallel to, perpendicular to, or extend in a direction that is between parallel and perpendicular to the lengthwise direction of the bit lines 128.

An anisotropic etch process can be performed to etch unmasked portions of the dielectric hardmask material of the dielectric hardmask layer 159L, the first main metal of the first main metal layer (158N, 158F), and the first metallic barrier material of the first metallic barrier liner 158B from above the first horizontal plane HP1 employing the patterned etch mask layer (such as the first patterned photoresist layer 157) as an etch mask. The anisotropic etch process may comprise a sequence of anisotropic etch steps for sequentially etching the dielectric hardmask material of the dielectric hardmask layer 159L, the first main metal of the first main metal layer (158N, 158F), and the first metallic barrier material of the first metallic barrier liner 158B. A terminal anisotropic etch step of the anisotropic etch process may etch the first metallic barrier material of the first metallic barrier liner 158B selective to the material of the via-level main dielectric layer 153.

Patterned remaining portions of the dielectric hardmask layer 159L comprise a plurality of dielectric hardmask rails 159. As used herein, a “rail” refers to a structure that laterally extends along a horizontal direction with a uniform vertical cross-sectional shape within any vertical plane that is perpendicular to the horizontal direction and cuts through the structure. In one embodiment, each dielectric hardmask rail 159 may have a respective vertical cross-sectional shape of a rectangle. The plurality of dielectric hardmask rails 159 may be formed at a same level. The plurality of dielectric hardmask rails 159 may be laterally spaced from each other as a periodic one-dimensional array.

Patterned portions of the first metal layer 158L comprise a plurality of first integrated line-and-via structures 158. Each first integrated line-and-via structure 158 comprises a respective contiguous set of remaining portions of the first main metal and the first metallic barrier material. Generally, the plurality of first integrated line-and-via structures 158 comprises a first integrated line-and-via structure 158 and additional first integrated line-and-via structures 158 that are formed at a same level. The plurality of first integrated line-and-via structures 158 may be laterally spaced from each other as a periodic one-dimensional array. Each first integrated line-and-via structure 158 comprises a combination of a first line portion 158L that overlies the first horizontal plane HP1 and a first via portion 158V that is located in the respective first via cavity 155 and underlies the first horizontal plane HP1.

Each first integrated line-and-via structure 158 comprises a first metallic barrier liner 158B and a first main metal portion (158N, 158F). The first metallic barrier liner 158B contains a vertically-extending portion that contacts a sidewall of the at least one via-level dielectric layer (151, 153) in the respective first via cavity 155 and a horizontally-extending portion that contacts a segment of a top surface of the at least one via-level dielectric layer (151, 153). The first main metal portion (158N, 158F) includes a planar portion (i.e., part of the line portion 158L) that overlies the horizontally-extending portion of the first metallic barrier liner 158B and has physically exposed sidewalls (such as a pair of physically exposed lengthwise sidewalls and a pair of physically exposed widthwise sidewalls), and further includes a vertically-extending portion (i.e., part of the via portion 158V) that protrudes downward from a bottom surface of the planar portion of the first main metal portion (158N, 158F) and is laterally surrounded by the vertically-extending portion of the first metallic barrier liner 158B.

According to an aspect of the present disclosure, each first line portion 158L and a respective overlying dielectric hardmask rail 159 may have a same area in a plan view (such as a top-down view), and may have a same lateral extent (such as a width) in a vertical cross-sectional view along a horizontal plane that is perpendicular to the lengthwise direction of the first line portions 158L. Thus, each dielectric hardmask rail 159 of the plurality of dielectric hardmask rails 159 may have a same area as and may have a same with as a respective first line portion 158L of a respective underlying one among the plurality of first integrated line-and-via structures 158.

Generally, a patterned portion of the first metallic barrier material and the first main metal may comprise a first integrated line-and-via structure 158 that includes a first via portion 158V embedded within the at least one via-level dielectric layer (151, 153), and a first line portion 158L overlying a first horizontal plane HP1 including a top surface of the at least one via-level dielectric layer (151, 153). A patterned portion of the dielectric hardmask material comprises a dielectric hardmask rail 159 that overlies the first line portion 158L. In one embodiment, a bottom surface of the first via portion 158V contacts a top surface of one of the metal lines (such as bit lines 128 or bit-line-level interconnect metal lines 126) embedded within an underlying dielectric material layer (such as the bit-line-level dielectric layer 120). The patterned etch mask layer (such as the first patterned photoresist layer 157) may be subsequently removed, for example, by ashing.

Referring to FIG. 6H, an interlayer dielectric (ILD) material can be deposited to form a dielectric matrix 173. The interlayer dielectric material may be deposited, for example, by plasma-enhanced chemical vapor deposition (PECVD) process. The interlayer dielectric material may comprise undoped silicate glass (i.e., silicon oxide), a doped silicate glass, or a porous or non-porous organosilicate glass. The interlayer dielectric material may be deposited with a planar top surface, or may be planarized after deposition to provide a planar top surface within a third horizontal plane HP3. The third horizontal plane HP3 is located above the horizontal plane including the top surfaces of the dielectric hardmask rails 159, which is herein referred to as a fourth horizontal plane HP4. The vertical distance between the third horizontal plane HP3 and the fourth horizontal plane HP4 may be in a range from 80 nm to 300 nm, such as from 100 nm to 200 nm, although lesser and greater vertical distances may also be employed.

In case the interlayer dielectric material of the dielectric matrix 173 is deposited such that the top surface of the dielectric matrix 173 has a topography that reflects the height variations of underlying structures, a chemical mechanical polishing process employed to subsequently form second integrated line-and-via structures can collaterally planarize the top surface of the dielectric matrix 173 such that the planarized top surface of the dielectric matrix 173 is formed within the third horizontal plane HP3. In other words, a planar top surface of the dielectric matrix 173 is formed within the third horizontal plane HP3 upon deposition of the dielectric matrix 173, after a planarization process that follows deposition of the dielectric matrix 172, or after a series of processing steps that includes a chemical mechanical processing process that forms second integrated line-and-via structures in an upper portion of the dielectric matrix 173.

The dielectric matrix 173 may be deposited as a single dielectric layer. Alternatively, the dielectric matrix 173 may be deposited using two different steps as two separate layers. In a first step, a lower portion (e.g., lower layer) 173A of the dielectric matrix 173 is deposited between vertical stacks (158, 159) of a respective first integrated line-and-via structure 158 and a respective dielectric hardmask rail 159. The lower portion 173A of the dielectric matrix 173 is then planarized by chemical mechanical polishing with the top of the vertical stacks (158, 159). The dielectric hardmask rails 159 can function as a polish stop, and the top of the lower portion 173A of the dielectric matrix 173 is located in the fourth horizontal plane HP4. The upper portion (e.g., upper layer) 173B of the dielectric matrix 173 may then be deposited over the lower portion 173A of the dielectric matrix 173 and over the vertical stacks (158, 159). The upper portion 173B and the lower portion 173A may comprise the same material (e.g., silicon oxide) or different material from each other.

In one embodiment, at least the lower portion 173A of the dielectric matrix 173 is formed by a anisotropic deposition process that deposits the interlayer dielectric material with sufficient non-conformity and directionality to avoid a complete gap fill in the gaps between neighboring pairs of vertical stacks (158, 159) to form air gaps (i.e., encapsulated cavities) 169 between neighboring pairs of vertical stacks (158, 159). The air gaps 169 are embedded within the dielectric matrix 173, and are formed between a respective neighboring pair among the plurality of first integrated line-and-via structure 158. In one embodiment, each of the air gaps 169 comprises a respective bottommost surface located between the first horizontal plane HP1 and the second horizontal plane HP2, and a respective topmost surface located between the second horizontal plane HP2 and a fourth horizontal plane HP4 including the top surfaces of the plurality of dielectric hardmask rails 159. The lateral extent of each air gap 169 along the direction of periodicity of the dielectric hardmask rails 159 and the first line portions 158L of the first integrated line-and-via structures 158 is less than the lateral spacing between neighboring pairs of vertical stacks (158, 159).

In summary, the dielectric matrix 173 is formed over over the dielectric hardmask rail 159 and the at least one via-level dielectric layer (151, 153). The dielectric matrix 173 can be deposited around and over the first integrated line-and-via structures 158 and the dielectric hardmask rails 159. In one embodiment, each first integrated line-and-via structure 158 may comprise a first via portion 158V embedded within at least one via-level dielectric layer (151, 153) and a first line portion 158L embedded within a lower portion of a dielectric matrix 173. The dielectric matrix 173 contacts a top surface of the at least one via-level dielectric layer (151, 153) within the first horizontal plane HP1. Each first integrated line-and-via structure 158 may comprise a first metallic barrier liner 158B and a first main metal portion (158N, 158F). The first metallic barrier liner 158B contains a vertically-extending portion that contacts a sidewall of the at least one via-level dielectric layer (151, 153) and a horizontally-extending portion that contacts a segment of a top surface of the at least one via-level dielectric layer (151, 153). The first main metal portion (158N, 158F) includes a planar portion that overlies the horizontally-extending portion of the first metallic barrier liner 158B and has sidewalls 158LS in direct contact with first surface segments of the dielectric matrix 173. The first main metal portion (158N, 158F) further includes a vertically-extending portion that protrudes downward from a bottom surface of the a planar portion of the first main metal portion (158N, 158F) and is laterally surrounded by the vertically-extending portion of the first metallic barrier liner 158B.

According to an aspect of the present disclosure, the first metal of the first main metal portion (158N, 158F) is in direct contact with the dielectric matrix 173 at the sidewalls of the first metal line portions 158L. In one embodiment, the vertical extent of an interface between the sidewalls 158LS of the first main metal portion (158N, 158F) of the line portion 158L and the dielectric matrix 173 may equal the height of the first line portion 158L less the thickness of the horizontally-extending portion of the first metallic barrier liner 158B. Each first via portion 158V of the first integrated line-and-via structures 158 may comprise a respective bottom surface that contact a top surface of a respective one of the metal lines (such as bit lines 128 or bit-line-level interconnect metal lines 126).

Each dielectric hardmask rail 159 may contact the entirety of the top surface of the first line portion 158L of a respective underlying first integrated line-and-via structure 158. Each dielectric hardmask rail 159 may comprise sidewalls that contact the dielectric matrix 173. For example, each dielectric hardmask rail 159 may comprise a respective pair of lengthwise sidewalls and a respective pair of widthwise sidewalls that contact the dielectric matrix 173. Each dielectric hardmask rail 159 may have a top surface that contacts the dielectric matrix 173 within the fourth horizontal plane HP4 that contains a horizontal bottom surface of the second line portion 178L of the second integrated line-and-via structure 178.

According to an aspect of the present disclosure, a pair of lengthwise sidewalls of each dielectric hardmask rail 159 can be vertically coincident with a pair of lengthwise sidewalls of the first line portion 158L of a respective underlying first integrated line-and-via structure 158. Likewise, a pair of widthwise sidewalls of each dielectric hardmask rail 159 can be vertically coincident with a pair of widthwise sidewalls of the first line portion 158L of a respective underlying first integrated line-and-via structure 158. As such, all edges of the top surface of the first line portion 158L of each first integrated line-and-via structure 158 may coincides with a respective edge of a bottom surface of a respective overlying dielectric hardmask rail 159. As used herein, a first surface and a second surface are “vertically coincident” if the second surface overlies or underlies the first surface and if there exists a vertical plane including the first surface and the second surface.

In one embodiment, the first main metal layer (158N, 158F) is patterned into integrated line-and-via structures using a semi-damascene process. In the semi-damascene process, the bottom portions (i.e., the via portions 158V) of the first main metal layer are formed in the first via cavities 155 (similar to a damascene process), while the upper portion (i.e., the line portion 158L) of the first main metal layer overlies the top surface of the via-level dielectric layer (151, 153), as shown in FIG. 6C. The upper portion of the first main metal layer is then photolithographically patterned into line portions 158L, as shown in FIG. 6G, to generate the integrated line-and-via structures (158V, 158L) using the semi-damascene process.

After the first main metal layer (e.g., tungsten layer) (158N, 158F) and the barrier liner 158B are patterned into first integrated line-and-via structures (158V, 158L), the dielectric matrix 173 is deposited directly on the tungsten surfaces of the metal line 158L surfaces of the first integrated line-and-via structures. This configuration lowers the overall resistance of the first integrated line-and-via structures (158V, 158L) due to the absence of a metallic nitride material on sidewalls 158LS of the metal line portion 158L. Tungsten also provides a lower resistivity than ruthenium. Furthermore, tungsten can be deposited into narrower aspect ratio first via cavities 155 than copper because of a smaller filling aspect ratio of tungsten compared to that of copper due to a difference in breakdown voltage between tungsten and copper. Thus, if the first via cavities 155 have a pitch less than 100 nm, then tungsten provides an improved quality line-and-via structure relative to copper. In one embodiment, the first via cavities 155 have a pitch of 60 nm to 95 nm, an aspect ratio (i.e., ratio of height to width) of 3 to 7.5, and a width of 10 nm to 45 nm. Thus, in one embodiment, the effective sheet resistance of the semi-damascene interconnect comprising first integrated line-and-via structure (158V, 158L) which includes the tungsten main metal and the tungsten nitride barrier line is lower than that of a dual damascene tungsten interconnects and semi-damascene ruthenium interconnect.

Referring to FIG. 6I, a first photoresist layer 175 can be applied over the dielectric matrix 173, and can be lithographically patterned to form discrete openings having a pattern of discrete line structures to be subsequently formed. The lateral extension directions of each discrete opening may parallel to, perpendicular to, or between parallel and perpendicular to the lengthwise direction of the dielectric hardmask rails 159. At least a subset, and preferably, a predominant subset (i.e., more than 50%), of the openings in the first photoresist layer 175 may have an areal overlap with a respective underlying vertical stack of a dielectric hardmask rail 159 and a first line portion 158L.

An anisotropic etch process can be performed to etch unmasked upper portion 173B of the dielectric matrix 173 from above the fourth horizontal plane HP4. Line cavities 179L can be formed in the volumes from which the material of the dielectric matrix 173 is removed. A segment of a top surface of an underlying dielectric hardmask rail 159 may be physically exposed underneath a predominant subset of the line cavities 179L. Thus, the dielectric hardmask rails 159 may be are used as etch stop structures. In one embodiment, a segment of a top surface of an underlying dielectric hardmask rail 159 may be physically exposed underneath each of the line cavities 179L. In one embodiment, at least another segment of the top surface of the underlying dielectric hardmask rail 159 may be covered by an unetched portion of the dielectric matrix 173. The first photoresist layer 175 can be subsequently removed, for example, by ashing.

It is noted that drawings are only schematic, and the various shapes of the line cavities 179L merely schematically represent that a surface segment of an underlying dielectric hardmask rail 159 may be physically exposed for a line cavity 179L, and another surface segment of the underlying dielectric hardmask rail 159 does not need to be physically exposed for the line cavity 179L. Generally, a line cavity 179L may be formed in an upper portion 173B of the dielectric matrix 173 such that a first portion of a dielectric hardmask rail 159 (i.e., a segment of a top surface of the dielectric hardmask rail 159) is exposed while a second portion of the dielectric hardmask rail 159 (i.e., another surface segment of the top surface of the dielectric hardmask rail 159) is not exposed.

Referring to FIG. 6J, a second photoresist layer 177 can be applied over the dielectric matrix 173 and in the line trenches 179L, and can be lithographically patterned to form openings in areas in which second via cavities 179V are to be subsequently formed. A second anisotropic etch process can be performed to unmasked portions of the dielectric hardmask rails 159 selective to the material of the dielectric matrix 173. The second anisotropic etch process is a selective etch process having an etch chemistry that etches the material of the dielectric hardmask rails 159 without significantly etching the material of the dielectric matrix 173 or the first main metal of the first line portions 158L. For example, if the dielectric hardmask layer 159 comprise silicon nitride, a phosphoric acid etch process may be used. Generally, the second via cavities 179V can be formed by removing unmasked first portions of the dielectric hardmask rails 159 without removing second masked portions of the dielectric hardmask rails 159. The second masked portions of the dielectric hardmask rails 159 may be covered by overlying portions of the dielectric matrix 173 and/or by overlying portions of the second photoresist layer 177.

Integrated line-and-via cavities 179 can be formed in an upper portion of the dielectric matrix 173. Each integrated line-and-via cavity 179 may comprise a line cavity 179L and at least one second via cavity 179V that is adjoined to the line cavity 179L. All, or a predominant portion, of the line cavity 179L of each integrated line-and-via cavity 179 may be formed above the fourth horizontal plane HP4 that includes the top surfaces of the dielectric hardmask rails 159. Each second via cavity 179V of the integrated line-and-via cavities 179 may be formed below the fourth horizontal plane HP4 and above the second horizontal plane HP2. A predominant subset, or all of the first line portions 158L may have a respective first top surface segment that is exposed to an overlying second via cavity 179V, and a respective second top surface segment that contacts a bottom surface of a respective overlying dielectric hardmask rail 159. The second photoresist layer 177 can be subsequently removed, for example, by ashing.

Referring to FIG. 6K, a metallic barrier liner material (such as TiN, TaN, WN, MON, Ti, Ta and/or a stack thereof) can be deposited in the integrated line-and-via cavities 179 and over the dielectric matrix 173 by a physical vapor deposition process or a chemical vapor deposition process. A metallic fill material (such as Cu, W, Mo, Ru, Co, etc.) may be deposited by electroplating, a physical vapor deposition process, or a chemical vapor deposition process. In one embodiment, the metal fill material comprises copper. A chemical mechanical polishing process can be performed to remove portions of the metallic fill material and the metallic barrier liner material from above the third horizontal plane. Remaining portions of the metallic fill material and the metallic barrier liner material filling the integrated line-and-via cavities comprise second integrated line-and-via structures 178. Thus, the second integrated line-and-via structures 178 are formed by a dual damascene process.

Each second integrated line-and-via structure 178 may be formed within a respective integrated line-and-via cavity, which includes a combined volume of a line cavity 179L and at least one second via cavity 179V. Each second integrated line-and-via structure 178 may comprise a second via portion 178V contacting a first segment of a top surface of the first line portion 158L of a respective first integrated line-and-via structure 158 within the second horizontal plane HP2, and may further comprise a second line portion 178L adjoined to a top end of the second via portion 178V and having a top surface within the third horizontal plane HP3 at which a top surface of the dielectric matrix 173 is located. Each second integrated line-and-via structure 178 may comprise a respective second metallic barrier liner 178B and a respective second main metal portion 178F. Each second main metal portion 178F is spaced from the dielectric matrix 173 by a respective second metallic barrier liner 178B, and thus, does not directly contact the dielectric matrix 173.

According to an aspect of the present disclosure, a pair of edges of a first segment of the top surface of the first line portion 158L of a first integrated line-and-via structure 158 may coincide with a pair of edges of a bottom surface of the second via portion 178V of an overlying second integrated line-and-via structure 178. In one embodiment, a pair of sidewalls 158LS of the first line portion 158L of the first integrated line-and-via structure 158 may be vertically coincident with a pair of sidewalls 178VS of the second via portion 178V of the overlying second integrated line-and-via structure 178. In one embodiment, a dielectric hardmask rail 159 can contact a second segment of the top surface of the first line portion 158L of the first integrated line-and-via structure 158, and can have a pair of sidewalls contacting the dielectric matrix 173. In one embodiment, the dielectric hardmask rail 159 has a top surface within the fourth horizontal plane HP4, which contains a horizontal bottom surface of the second line portion 178L of the second integrated line-and-via structure 178. In one embodiment, a pair of edges of the second segment of the top surface of the first line portion 158L of the first integrated line-and-via structure 158 coincides with a pair of edges of a bottom surface of the dielectric hardmask rail 159. In one embodiment, a pair of sidewalls of the first line portion 158L of the first integrated line-and-via structure 158 is vertically coincident with a pair of sidewalls of the dielectric hardmask rail 159.

According to an aspect of the present disclosure, each surface segment of the top surface of the first line portions 158L of the first integrated line-and-via structures 158 may be contacted by a respective dielectric hardmask rail 159 or by a respective second via portion 178V of the second integrated line-and-via structures 178. In one embodiment, each surface that contacts the top surface of the first line portion 158L of the first integrated line-and-via structure 158 has a material composition of the dielectric hardmask rail 159 or has a material composition of a bottom surface of the second via portion 178V.

Upper-level dielectric material layers and upper-level metal interconnect structures can be subsequently formed. For example, the upper-level dielectric material layers may comprise an upper-level etch-stop dielectric layer (e.g., a silicon carbonitride layer) 181 and an upper-level main dielectric layer (e.g., a silicon oxide layer) 183.

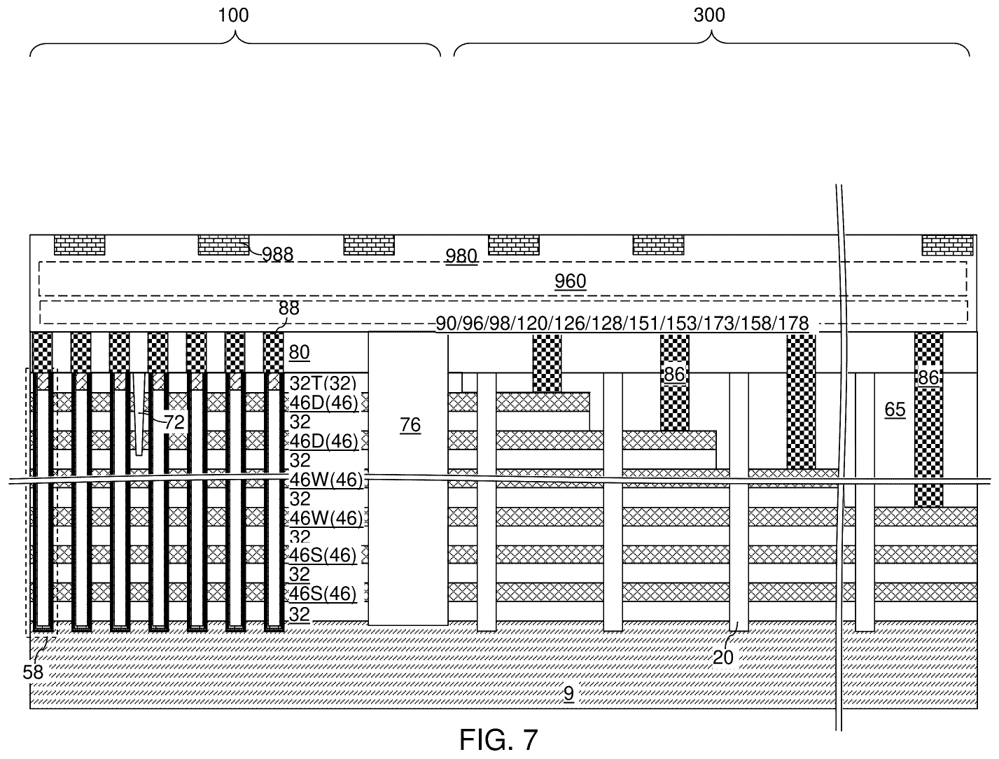

Referring to FIG. 7, additional dielectric material layers (which may include, for example, the upper-level etch-stop dielectric layer 181 and the upper-level main dielectric layer 183) and additional metal interconnect structures can be formed over the dielectric matrix 173 and the second integrated line-and-via structures 178. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the dielectric matrix 173 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

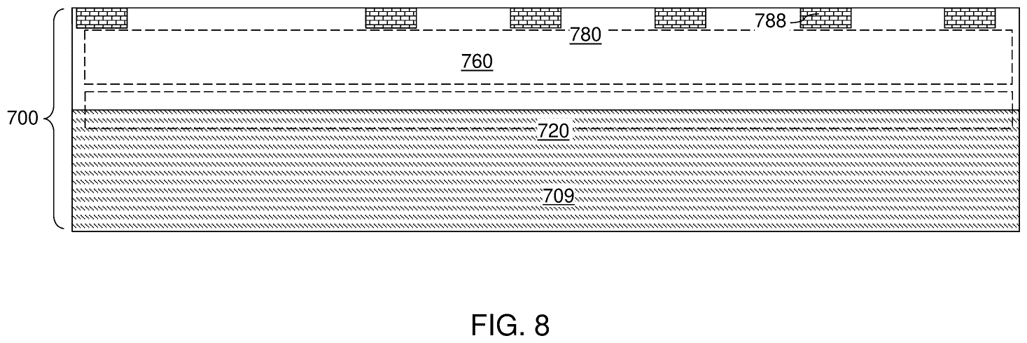

Referring to FIG. 8, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines 46W in the memory die 900.

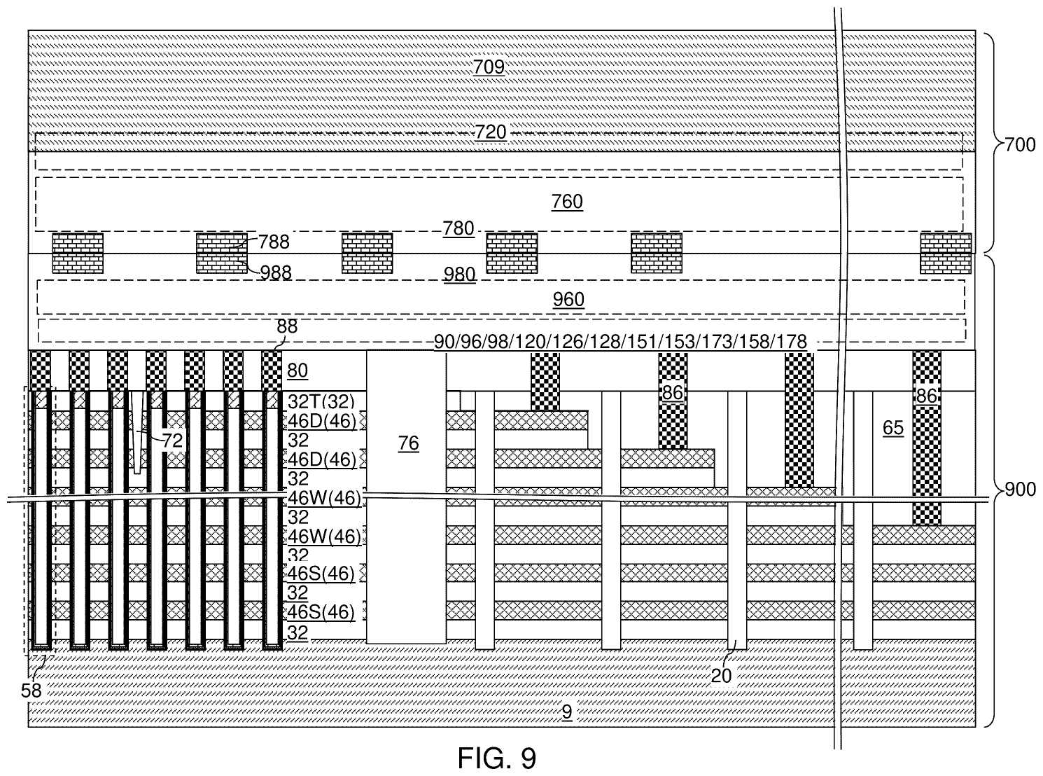

Referring to FIG. 9, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

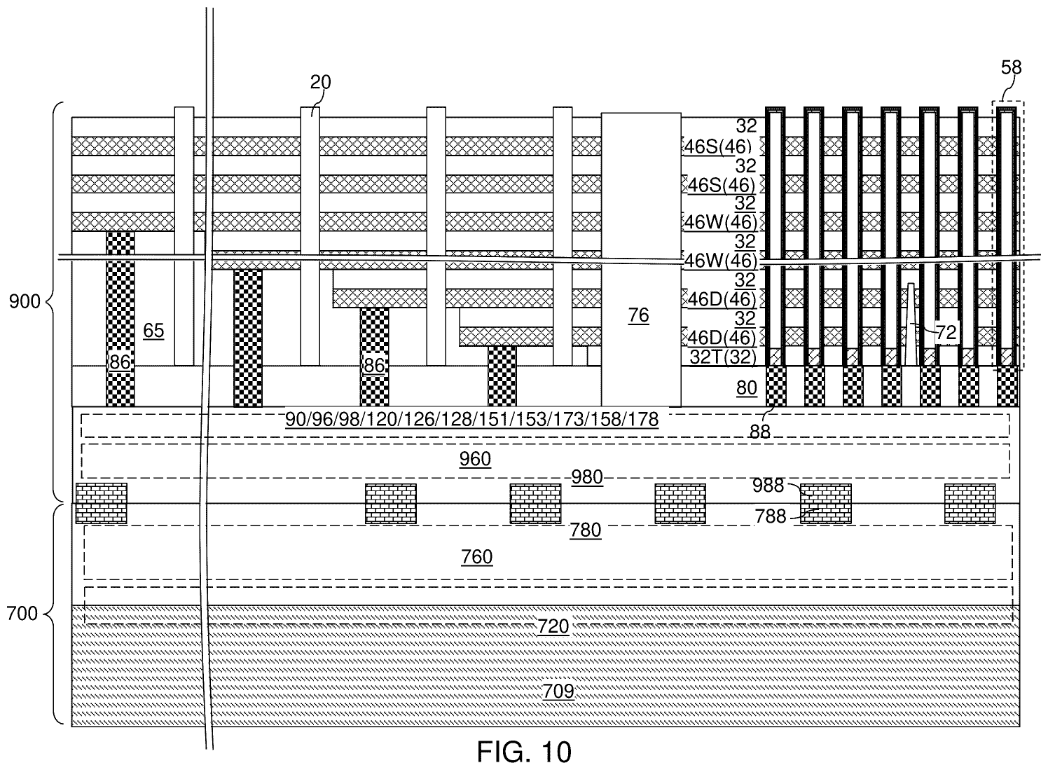

Referring to FIG. 10, the substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

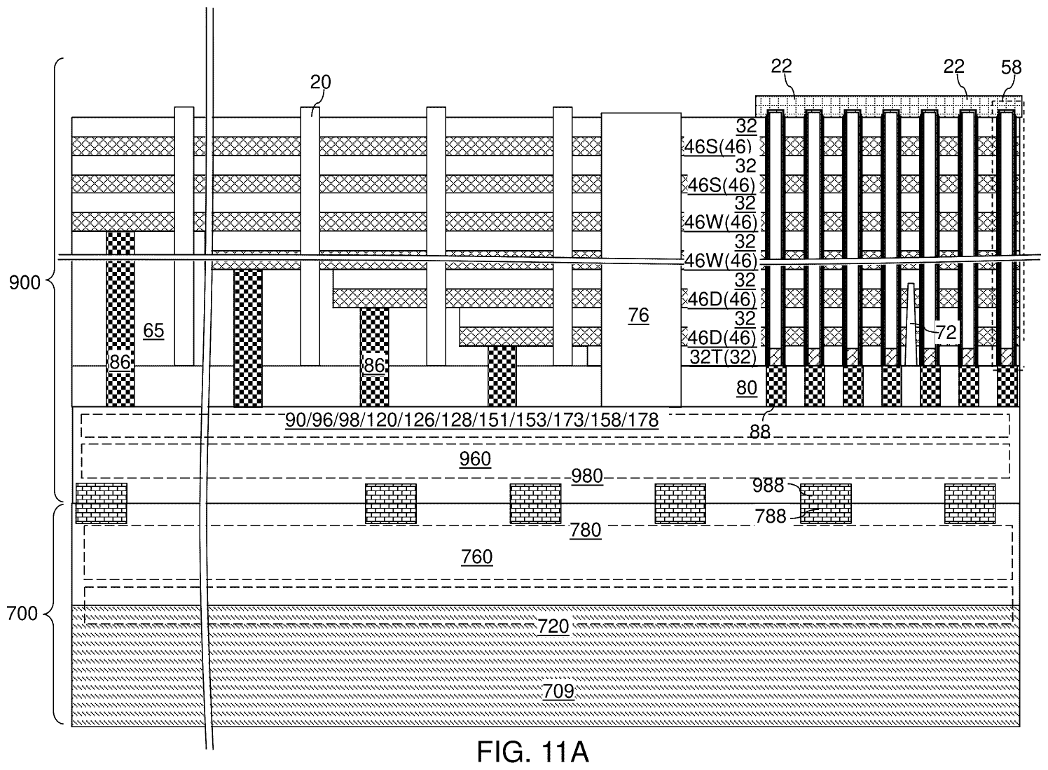

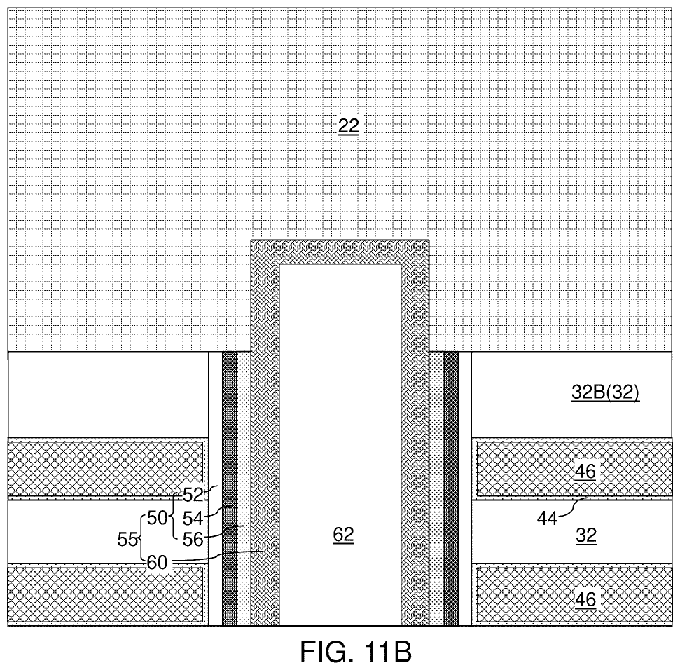

Referring to FIGS. 11A and 11B, an end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

One or more source structures (e.g., one or more source lines) 22 can be formed in contact vertical semiconductor channels 60. The source structure 22 may comprise a heavily doped semiconductor material and/or a metallic material (e.g., a metal and/or an electrically conductive metal nitride or silicide). Optional outer blocking dielectric layers 44 are illustrated in FIG. 11B, each of which embeds a respective electrically conductive layer 46. Alternatively, the optional outer blocking dielectric layers 44 may be omitted.

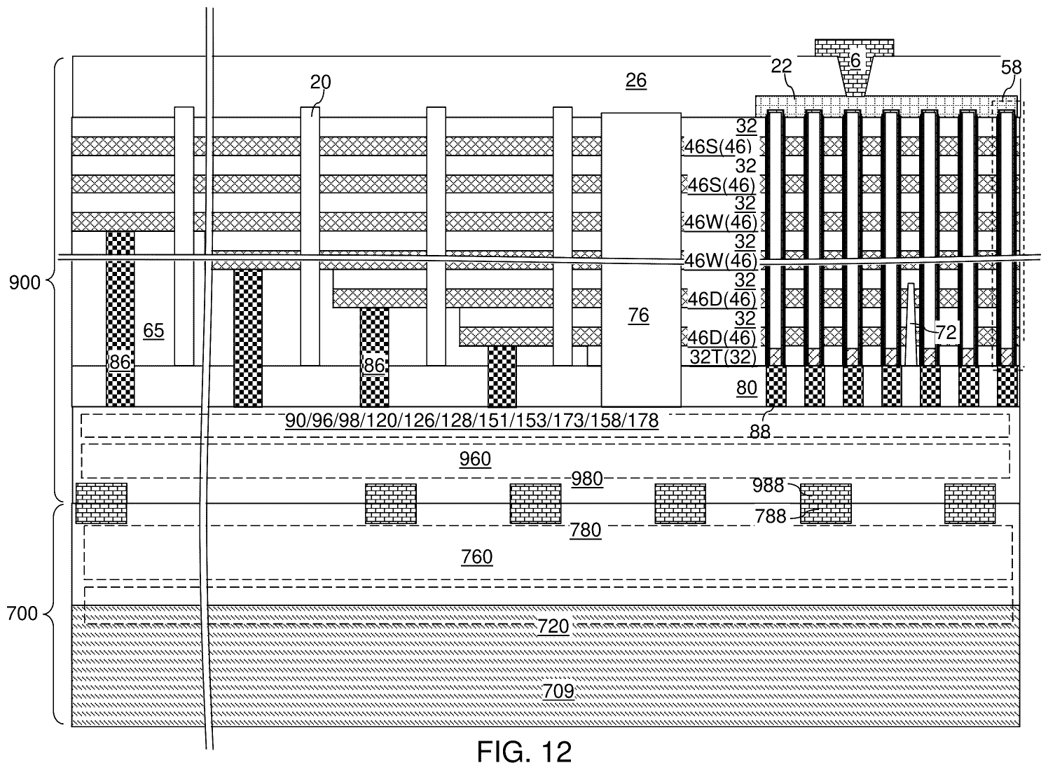

Referring to FIG. 12, a backside dielectric layer 26 and source contact structures 6 can be subsequently formed in contact with the one or more source structures 22.

While a bonded assembly of a memory die 900 and the logic die 700 are described above, in an alternative embodiment, the peripheral circuit 720 and the memory array (32, 46, 58) may be located in the same die. In this alternative embodiment, the peripheral circuit 720 may be formed over the substrate 9 and the memory array (32, 46, 58) is then formed over the peripheral circuit 720.

Referring to all drawings and according to various embodiments of the present disclosure, a device structure comprises: a first integrated line-and-via structure 158 comprising a first via portion 158V embedded within at least one via-level dielectric layer (151, 153) and a first line portion 158L embedded within a lower portion of a dielectric matrix 173 that contacts a top surface of the at least one via-level dielectric layer (151, 153) within a first horizontal plane HP1, wherein the first integrated line-and-via structure 158 comprises a first metallic barrier liner 158B containing a vertically-extending portion that contacts a sidewall of the at least one via-level dielectric layer (151, 153) and a horizontally-extending portion that contacts a segment of a top surface of the at least one via-level dielectric layer (151, 153), and further comprises a first main metal portion (158N, 158F) including a planar portion that overlies the horizontally-extending portion of the first metallic barrier liner 158B and has sidewalls in direct contact with first surface segments of the dielectric matrix 173; and a second integrated line-and-via structure 178 comprising a second via portion 178V contacting a first segment of a top surface of the first line portion 158L of the first integrated line-and-via structure 158 within a second horizontal plane HP2 and further comprising a second line portion 178L adjoined to a top end of the second via portion 178V.

In one embodiment, the second line portion has a top surface within a third horizontal plane HP3 at which a top surface of the dielectric matrix 173 is located.

In one embodiment, a pair of edges of the first segment of the top surface of the first line portion 158L of the first integrated line-and-via structure 158 coincides with a pair of edges of a bottom surface of the second via portion 178V of the second integrated line-and-via structure 178. In one embodiment, a pair of sidewalls of the first line portion 158L of the first integrated line-and-via structure 158 is vertically coincident with a pair of sidewalls of the second via portion 178V of the second integrated line-and-via structure 178. In one embodiment, a vertical extent of an interface between the one of the sidewalls of the first main metal portion (158N, 158F) and the dielectric matrix 173 equals a height of the first line portion 158L less a thickness of the horizontally-extending portion of the first metallic barrier liner 158B.

In one embodiment, the first main metal portion (158N, 158F) further comprises a vertically-extending portion that is located in the first via portion 158V and that protrudes downward from a bottom surface of the a planar portion of the first main metal portion (158N, 158F) and is laterally surrounded by the vertically-extending portion of the first metallic barrier liner 158B. In one embodiment, the device structure comprises metal lines (such as bit lines 128 and/or bit-line-level interconnect metal lines 126) that are parallel to each other and embedded within a line-level dielectric layer (such as a bit-line-level dielectric layer 120) that underlies the via-level dielectric layer (151, 153), wherein a bottom surface of the first via portion 158V contacts a top surface of one of the metal lines (such as bit lines 128).

In one embodiment, the metal lines comprise copper bit lines 128 of a memory device and copper bit-line-level interconnect metal lines 126 that provide an electrical connection between word lines 46 of the memory device and a word line driver circuit 720; the first metallic barrier liner 158B comprises tungsten nitride; the first main metal portion (158N, 158F) comprises tungsten; and the second integrated line-and-via structure comprises a copper second main metal portion 178F and a second metallic barrier liner 178B.

In one embodiment, the device structure further comprises a dielectric hardmask rail 159 that contacts a second segment of the top surface of the first line portion 158L of the first integrated line-and-via structure 158 and having a pair of sidewalls contacting the dielectric matrix 173. In one embodiment, the dielectric hardmask rail 159 has a top surface within a fourth horizontal plane HP4 that contains a horizontal bottom surface of the second line portion 178L of the second integrated line-and-via structure 178. In one embodiment, a pair of edges of the second segment of the top surface of the first line portion 158L of the first integrated line-and-via structure 158 coincides with a pair of edges of a bottom surface of the dielectric hardmask rail 159. In one embodiment, a pair of sidewalls of the first line portion 158L of the first integrated line-and-via structure 158 is vertically coincident with a pair of sidewalls of the dielectric hardmask rail 159.

In one embodiment, the top surface of the first line portion 158L of the first integrated line-and-via structure 158 contacts the dielectric hardmask rail 159 and the bottom surface of the second via portion 178V.

In one embodiment, the device structure further comprises: a plurality of first integrated line-and-via structures 158 that includes the first integrated line-and-via structure 158 and additional first integrated line-and-via structures 158, wherein the plurality of first integrated line-and-via structures 158 are laterally spaced apart from each other; and a plurality of dielectric hardmask rails 159 that includes the dielectric hardmask rail 159 and additional dielectric hardmask rails 159, wherein each dielectric hardmask rail 159 of the plurality of dielectric hardmask rails 159 has a same width as a respective first line portion 158L of a respective underlying one of the plurality of first integrated line-and-via structures 158.

In one embodiment, the device structure further comprises air gaps 169 embedded within the dielectric matrix 173 and located between a respective neighboring pair among the plurality of first integrated line-and-via structure 158. In one embodiment, each of the air gaps 169 comprises a respective bottommost surface located between the first horizontal plane HP1 and the second horizontal plane HP2, and a respective topmost surface located between the second horizontal plane HP2 and a fourth horizontal plane HP4 including top surfaces of the plurality of dielectric hardmask rails 159.

In one embodiment, a three-dimensional memory device 900 comprises an alternating stack of insulating layers 32 and word lines 46W; memory opening fill structures 58 extending through the alternating stack and each comprising a memory film 50, a vertical semiconductor channel 60, and a drain region 63; copper bit lines 128 electrically connected to the drain regions 63; copper bit-line-level interconnect metal lines 126 located at a same level as the copper bit lines 128 and electrically connected to the word lines 46W; first integrated line-and-via structures 158 contacting the respective copper bit lines 128 and copper bit-line-level interconnect metal lines 126, and comprising a tungsten nitride metallic barrier liner 158B and a tungsten first main metal portion (158N, 158F); and second integrated line-and-via structures 178 contacting the respective first integrated line-and-via structures 158 and comprising a second metallic barrier liner 178B and a copper second main metal portion 178F.

In one embodiment, a dielectric matrix 173 is located in contact with sidewalls of the tungsten first main metal portion (158N, 158F). Air gaps 169 may be located in the dielectric matrix 173 between the first integrated line-and-via structures 158. The memory device 900 may also include silicon nitride rails 159 that contact a top surface of the first integrated line-and-via structures 158 and have a pair of sidewalls contacting the dielectric matrix 173.

The first line portions 158L of the first integrated line-and-via structures 158 provide lower resistance due to absence of vertically-extending portions of the first metallic barrier liner 158B. This configuration reduces volumes occupied by the first metallic barrier line 158B within each first line portion 158L, and increases the overall conductivity of the first line portions 158L. Furthermore, the optional incorporation of air gaps 169 in the dielectric matrix 173 lowers the effective dielectric constant in the regions between neighboring pairs of the first line portions 158L. As a result, the RC delay in the signal propagation through the first line portions 158L can be significantly reduced.

Further, the second via cavities 179V are formed through selective etching of unmasked portions of the dielectric hardmask rails 159. Thus, the lateral extents of the second via cavities 179V are self-aligned to the lateral extents of the dielectric hardmask rails 159 and the first line portions 158L. As a consequence, the second via portions 178V of the second integrated line-and-via structures 178 are self-aligned to the first line portions 158L of the first integrated line-and-via structures 158. This self-alignment configuration minimizes the risk of electrical shorts, and increases the reliability of the electrical contacts within the metal interconnect structures of the present disclosure.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a first integrated line-and-via structure comprising a first via portion embedded within at least one via-level dielectric layer and a first line portion embedded within a lower portion of a dielectric matrix that contacts a top surface of the at least one via-level dielectric layer within a first horizontal plane, wherein the first integrated line-and-via structure comprises a first metallic barrier liner containing a vertically-extending portion that contacts a sidewall of the at least one via-level dielectric layer and a horizontally-extending portion that contacts a segment of a top surface of the at least one via-level dielectric layer, and further comprises a first main metal portion including a planar portion that overlies the horizontally-extending portion of the first metallic barrier liner and has sidewalls in direct contact with first surface segments of the dielectric matrix; and
a second integrated line-and-via structure comprising a second via portion contacting a first segment of a top surface of the first line portion of the first integrated line-and-via structure within a second horizontal plane and further comprising a second line portion adjoined to a top end of the second via portion.

2. The device structure of claim 1, wherein the second line portion has a top surface within a third horizontal plane at which a top surface of the dielectric matrix is located.

3. The device structure of claim 1, wherein:
a pair of edges of the first segment of the top surface of the first line portion of the first integrated line-and-via structure coincides with a pair of edges of a bottom surface of the second via portion of the second integrated line-and-via structure;
a pair of sidewalls of the first line portion of the first integrated line-and-via structure is vertically coincident with a pair of sidewalls of the second via portion of the second integrated line-and-via structure; and
a vertical extent of an interface between the one of the sidewalls of the first main metal portion and the dielectric matrix equals a height of the first line portion less a thickness of the horizontally-extending portion of the first metallic barrier liner.

4. The device structure of claim 1, wherein the first main metal portion further comprises a vertically-extending portion that is located in the first via portion and protrudes downward from a bottom surface of the planar portion of the first main metal portion and is laterally surrounded by the vertically-extending portion of the first metallic barrier liner.

5. The device structure of claim 1, further comprising metal lines that are parallel to each other and embedded within a line-level dielectric layer that underlies the via-level dielectric layer, wherein a bottom surface of the first via portion contacts a top surface of one of the metal lines.

6. The device structure of claim 1, wherein:
the metal lines comprise copper bit lines of a memory device and copper bit-line-level interconnect metal lines that provide an electrical connection between word lines of the memory device and a word line driver circuit;
the first metallic barrier liner comprises tungsten nitride;
the first main metal portion comprises tungsten; and
the second integrated line-and-via structure comprises a copper second main metal portion and a second metallic barrier liner.

7. The device structure of claim 1, further comprising a dielectric hardmask rail that contacts a second segment of the top surface of the first line portion of the first integrated line-and-via structure and having a pair of sidewalls contacting the dielectric matrix.

8. The device structure of claim 7, wherein:
the dielectric hardmask rail has a top surface within a fourth horizontal plane that contains a horizontal bottom surface of the second line portion of the second integrated line-and-via structure;
a pair of edges of the second segment of the top surface of the first line portion of the first integrated line-and-via structure coincides with a pair of edges of a bottom surface of the dielectric hardmask rail; and
a pair of sidewalls of the first line portion of the first integrated line-and-via structure is vertically coincident with a pair of sidewalls of the dielectric hardmask rail.

9. The device structure of claim 7, wherein the top surface of the first line portion of the first integrated line-and-via structure contacts the dielectric hardmask rail and a bottom surface of the second via portion.

10. The device structure of claim 1, wherein the device structure further comprises:
a plurality of first integrated line-and-via structures that includes the first integrated line-and-via structure and additional first integrated line-and-via structures, wherein the plurality of first integrated line-and-via structures are laterally spaced apart from each other; and
a plurality of dielectric hardmask rails that includes the dielectric hardmask rail and additional dielectric hardmask rails, wherein each dielectric hardmask rail of the plurality of dielectric hardmask rails has a same width as a respective first line portion of a respective underlying one of the plurality of first integrated line-and-via structures.

11. The device structure of claim 10, further comprising an air gaps embedded within the dielectric matrix and between a respective neighboring pair of the plurality of first integrated line-and-via structures, wherein each of the air gaps comprises a respective bottommost surface located between the first horizontal plane and the second horizontal plane, and a respective topmost surface located between the second horizontal plane and a fourth horizontal plane including top surfaces of the plurality of dielectric hardmask rails.

12. A three-dimensional memory device, comprising:
an alternating stack of insulating layers and word lines;
memory opening fill structures extending through the alternating stack and each comprising a memory film, a vertical semiconductor channel, and a drain region;
copper bit lines electrically connected to the drain regions;
copper bit-line-level interconnect metal lines located at a same level as the copper bit lines and electrically connected to the word lines;
first integrated line-and-via structures contacting the respective copper bit lines and copper bit-line-level interconnect metal lines, and comprising a tungsten nitride metallic barrier liner and a tungsten first main metal portion; and
second integrated line-and-via structures contacting the respective first integrated line-and-via structures and comprising a second metallic barrier liner and a copper second main metal portion.

13. The three-dimensional memory device of claim 12, further comprising a dielectric matrix located in contact with sidewalls of the tungsten first main metal portion.

14. The three-dimensional memory device of claim 13, further comprising air gaps located in the dielectric matrix between the first integrated line-and-via structures.

15. The three-dimensional memory device of claim 13, further comprising silicon nitride rails that contact a top surface of the first integrated line-and-via structures and having a pair of sidewalls contacting the dielectric matrix.

16. A method of forming device structure, comprising:
forming a first via cavity through at least one via-level dielectric layer;
depositing and patterning a first metallic barrier material, a first main metal, and a dielectric hardmask material over the at least one via-level dielectric layer, wherein a patterned portion of the first metallic barrier material and the first main metal comprises a first integrated line-and-via structure that includes a first via portion embedded within the at least one via-level dielectric layer and a first line portion overlying a first horizontal plane including a top surface of the at least one via-level dielectric layer, and a patterned portion of the dielectric hardmask material comprises a dielectric hardmask rail that overlies the first line portion;
forming a dielectric matrix over the dielectric hardmask rail and the at least one via-level dielectric layer;
forming a line cavity in an upper portion of the dielectric matrix such that a first portion of the dielectric hardmask rail is exposed while a second portion of the dielectric hardmask rail is not exposed;
forming a second via cavity by removing the first portion of the dielectric hardmask rail without removing the second portion of the dielectric hardmask rail; and
forming a second integrated line-and-via structure in a combined volume of the line cavity and the second via cavity.

17. The method of claim 16, further comprising:
forming a patterned etch mask layer over the dielectric hardmask material; and
performing an anisotropic etch process that etches unmasked portions of the dielectric hardmask material, the first main metal, and the first metallic barrier material from above the first horizontal plane employing the patterned etch mask layer as an etch mask, wherein:
a combination of remaining portions of the first main metal and the first metallic barrier material comprises the first integrated line-and-via structure; and
a remaining portion of the dielectric hardmask material comprises the dielectric hardmask rail.

18. The method of claim 16, wherein the second via cavity is formed by performing a selective anisotropic etch process that etches a material of the dielectric hardmask rail selective to materials of the dielectric matrix and the first main metal.

19. The method of claim 16, wherein:
additional patterned portions of the first metallic barrier material and the first main metal comprise additional first integrated line-and-via structures;
additional patterned portions of the dielectric hardmask material comprise additional dielectric hardmask rails; and
the dielectric matrix is deposited around the first integrated line-and-via structure, the additional first integrated line-and-via structures, the dielectric hardmask rail, and the additional dielectric hardmask rails.

20. The method of claim 16, wherein:
the first integrated line-and-via structure is formed by a semi-damascene process;
the first metallic barrier material comprises tungsten nitride and the first main metal comprises tungsten; and
second integrated line-and-via structure comprising a second metallic barrier liner and a copper second main metal portion is formed by a dual damascene process in contact with the first integrated line-and-via structure.
